(19) United States
(12) Patent Application Publication
(10) Pub. No.: US 2026/0344200 A1
(43) Pub. Date: Oct. 29, 2026

(54) DISPLAY DEVICE, ELECTRONIC DEVICE, AND METHOD FOR FABRICATING DISPLAY DEVICE

(71) Applicant: Samsung Display Co., LTD., Yongin-si (KR)

(72) Inventors: Joon Yong PARK, Yongin-si (KR); Young Min KIM, Yongin-si (KR); Eun Yeong KIM, Yongin-si (KR); Hyoung Sun PARK, Yongin-si (KR); Sung Hun YOON, Yongin-si (KR); Dong Min LEE, Yongin-si (KR); Min Young LEE, Yongin-si (KR); Sang Wook LEE, Yongin-si (KR); Yung Bin CHUNG, Yongin-si (KR)

(21) Appl. No.: 19/449,785

(22) Filed: Jan. 15, 2026

(30) Foreign Application Priority Data
Apr. 25, 2025 (KR) 10-2025-0054547

(51) Int. Cl. H10K 59/123; H10K 59/12; H10K 71/60; H10K 102/00; H10K 102/10

(52) U.S. Cl. CPC H10K 59/123; H10K 59/1201; H10K 71/60; H10K 2102/103; H10K 2102/351

(57) ABSTRACT

A display device includes: a substrate including a sub-pixel area; a transistor on the substrate; a first insulating layer on the transistor; a connection electrode on the first insulating layer and connected to the transistor; a second insulating layer on the connection electrode; a reflective electrode on the second insulating layer and connected to the connection electrode; a first electrode on the reflective electrode; a light emitting stack layer on the first electrode; and a second electrode on the light emitting stack layer. The reflective electrode and the first electrode are on the sub-pixel area, the reflective electrode includes: a first layer on the second insulating layer and connected to the connection electrode; a second layer on the first layer and including silver; and a third layer on the second layer and including a transparent conductive oxide in an amorphous state at 260 degrees in Celsius or less.

This application claims priority to Korean Patent Application No. 10-2025-0054547 filed on Apr. 25, 2025, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device, an electronic device, and a method for fabricating a display device capable of solving a problem of electrical short circuit between reflective electrodes of adjacent sub-pixel areas.

### 2. Description of the Related Art

An organic light emitting display device may include a display element whose luminance is changed by current, for example, an organic light emitting diode.

### SUMMARY

Aspects of the present disclosure provide a display device, an electronic device, and a method for fabricating a display device capable of solving a problem of electrical short-circuit between reflective electrodes of adjacent sub-pixel areas.

According to an aspect of the present disclosure, there is provided a display device including: a substrate including a sub-pixel area and a non-pixel area; a transistor on the substrate; a first insulating layer on the transistor; a connection electrode disposed on the first insulating layer and connected to the transistor; a second insulating layer on the connection electrode; a reflective electrode disposed on the second insulating layer and connected to the connection electrode; a first electrode on the reflective electrode; a light emitting stack layer on the first electrode; and a second electrode on the light emitting stack layer, where the reflective electrode and the first electrode are disposed on the sub-pixel area, the reflective electrode includes: a first layer disposed between the second insulating layer and the first electrode and connected to the connection electrode; a second layer disposed between the first layer and the first electrode and including silver; and a third layer between the second layer and the first electrode, the third layer and the second layer are in direct contact with each other, and the third layer includes a transparent conductive oxide and is in an amorphous state at 260 degrees in Celsius or less after deposition.

The third layer may have a thickness of about 300 angstroms (Å).

A total thickness summing a thickness of the first electrode and a thickness of the third layer may be 150 Å to 700 Å.

A thickness of the third reflective layer may be 30 Å to 150 Å, and a total thickness summing the thickness of the third reflective layer and a thickness of the fourth reflective layer may be about 300 Å.

According to another aspect of the present disclosure, there is provided an electronic device including: a processor; a memory connected to the processor; and a display device connected to the processor and the memory, where the display device includes: a substrate including a sub-pixel area and a non-pixel area; a transistor on the substrate; a first insulating layer on the transistor; a connection electrode disposed on the first insulating layer and connected to the transistor; a second insulating layer on the connection electrode; a reflective electrode disposed on the second insulating layer and connected to the connection electrode; a first electrode on the reflective electrode; a light emitting stack layer on the first electrode; and a second electrode on the light emitting stack layer, where the reflective electrode and the first electrode are disposed on the sub-pixel area, the reflective electrode includes: a first layer disposed between the second insulating layer and the first electrode and connected to the connection electrode; a second layer disposed between the first layer and the first electrode and including silver; and a third layer between the second layer and the first electrode, the third layer and the second layer are in direct contact with each other, and the third layer includes a transparent conductive oxide and is in an amorphous state at 260 degrees in Celsius or less after deposition.

According to still another aspect of the present disclosure, there is provided a method for fabricating a display device, the method includes: preparing a substrate including a first sub-pixel area, a second sub-pixel area, and a non-pixel area; forming a first transistor and a second transistor on the substrate; forming a first insulating layer on the first transistor and the second transistor; forming a first connection electrode connected to the first transistor and a second connection electrode connected to the second transistor on the first insulating layer; forming a second insulating layer on the first connection electrode and the second connection electrode; forming a first contact hole exposing the first connection electrode and a second contact hole exposing the second connection electrode in the second insulating layer; forming, on the second insulating layer, a first preliminary layer connected to the first connection electrode and the second connection electrode through the first contact hole and the second contact hole, respectively, and including amorphous ITO; forming a second preliminary layer on the first preliminary layer; forming a third preliminary layer including an amorphous transparent conductive oxide on the second preliminary layer; forming a resonance control layer on the third preliminary layer of the second sub-pixel area; forming a first preliminary electrode on the third preliminary layer and the resonance control layer; forming a photoresist pattern on the first preliminary electrode of the first sub-pixel area and the second sub-pixel area; forming a first_first reflective layer connected to the first connection electrode, a first_second reflective layer disposed on the first_first reflective layer, a first_third reflective layer disposed on the first_second reflective layer, and a first_first electrode disposed on the first_third reflective layer in the first sub-pixel area, and forming a second_first reflective layer connected to the second connection electrode, a second_second reflective layer disposed on the second_first reflective layer, a second_third reflective layer disposed on the second_second reflective layer, and a second_first electrode disposed on the second_third reflective layer and the resonance control layer in the second sub-pixel area, by patterning the first preliminary layer, the second preliminary layer, the third preliminary layer, and the first preliminary electrode using the photoresist pattern as a mask; forming a capping layer on edges of the first_first electrode and the second_first electrode and on the second insulating layer of the non-pixel area; and heat treating the capping layer, where before the heat treating of the capping layer, the first_first reflective layer, the first_first electrode, the second_first reflective layer, and the second_first electrode each include an amorphous ITO material, and after the heat treating of the capping layer, the first_first reflective layer, the first_first electrode, the second_first reflective layer, and the second_first electrode each include a crystalline ITO material, and before the first_first electrode and the second_first electrode are formed, the first_third reflective layer and the second_third reflective layer each include an amorphous transparent conductive oxide.

According to the display device, the electronic device, and the method for fabricating a display device according to an embodiment, the problem of electrical short-circuit between the reflective electrodes of the adjacent sub-pixel areas may be solved.

For example, the reflective electrode of the display device according to an embodiment may include a transparent conductive oxide that may be maintained in an amorphous state at high temperatures, and accordingly, when the first electrode (e.g., the anode electrode) and the reflective electrode are patterned, no residue (e.g., ITO residue) is formed between the adjacent sub-pixel areas (e.g., the non-pixel area). Accordingly, the problem of short circuit in which reflective electrodes of the adjacent sub-pixel areas are connected to each other may be solved.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view illustrating a display device according to an embodiment;

FIG. 2 is a block diagram illustrating the display device according to an embodiment;

FIG. 3 is a cross-sectional view of the display device according to an embodiment;

FIG. 4 is an enlarged view of area A of FIG. 3;

FIGS. 5, 6, 7, 8, 9, 10, 11, and 12 are process cross-sectional views for describing a method for fabricating a display device according to an embodiment;

FIG. 13 is a cross-sectional view of the display device according to an embodiment;

FIG. 14 is an enlarged view of area B of FIG. 13;

FIG. 15 is a cross-sectional view for describing a configuration of a third layer according to an embodiment;

FIGS. 16, 17, 18, 19, 20, 21, and 22 are process cross-sectional views for describing a method for fabricating a display device according to an embodiment;

FIG. 23 is a photograph of a non-pixel area of the display device according to an embodiment;

FIG. 24 is a block diagram of an electronic device according to an embodiment; and

FIGS. 25, 26, and 27 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification. In the attached figures, the thickness of layers and regions is exaggerated for clarity.

Although the terms "first", "second", “first_first”, “first_second”, “second_first”, “second_second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

"About" or "substantially equal" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 10%, 5% or 2% of the stated value. Hereinafter, specific exemplary embodiments will be described with reference to the accompanying drawings.

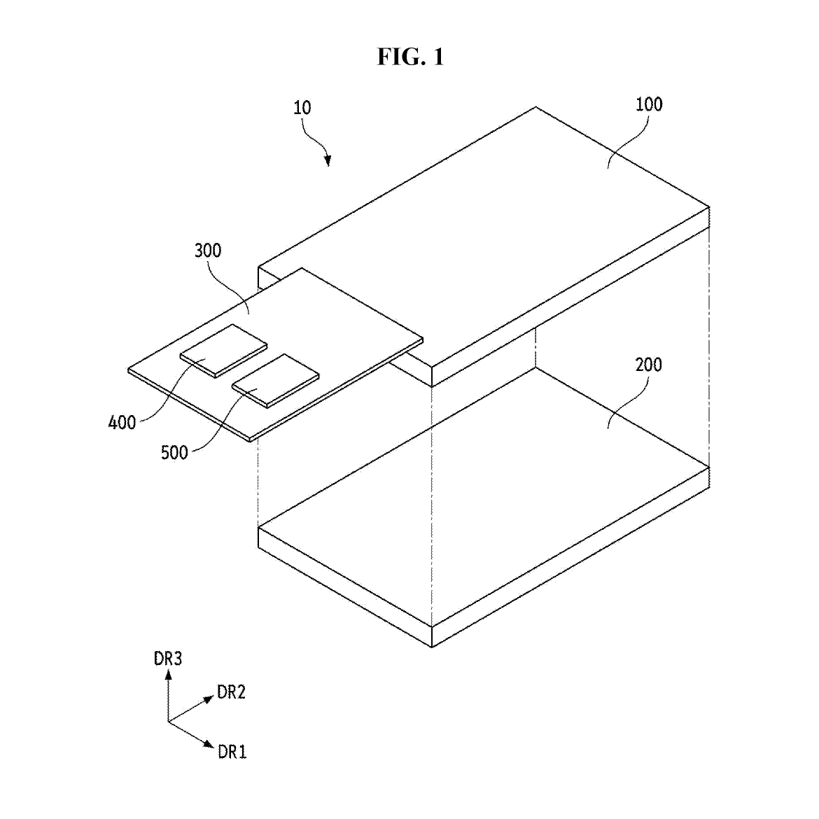

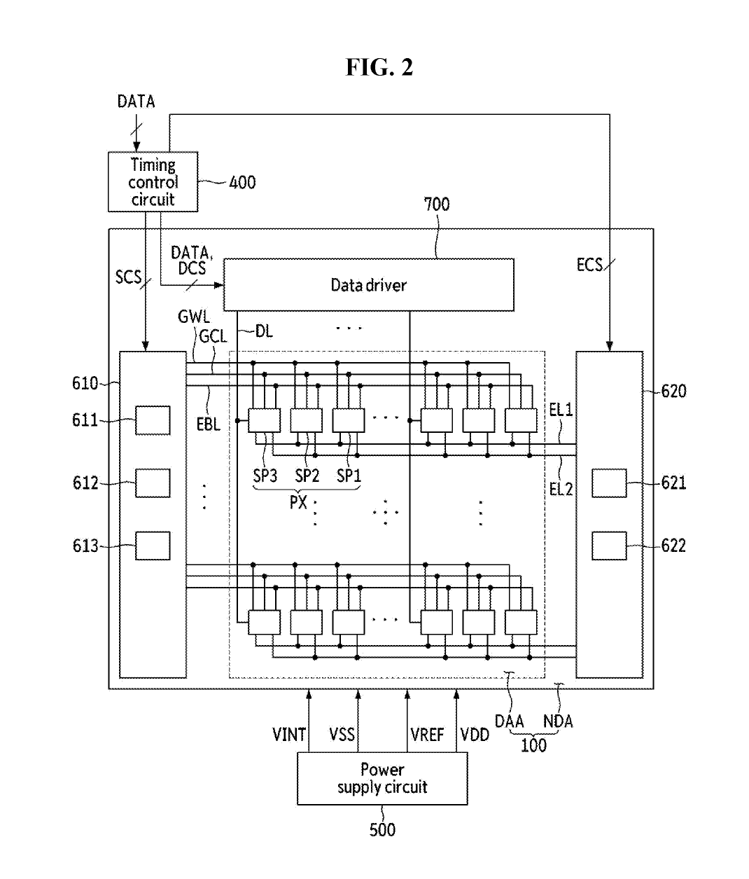

FIG. 1 is an exploded perspective view illustrating a display device according to an embodiment. FIG. 2 is a block diagram illustrating the display device according to an embodiment.

Referring to FIGS. 1 and 2, a display device 10 according to an embodiment is a device displaying a moving image or a still image. The display device 10 according to an embodiment may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to an embodiment may be applied to a display unit of a television, a laptop computer, a monitor, a billboard, or the Internet of Things (IoT). Alternatively, the display device 10 according to an embodiment may be applied to a smart watch, a watch phone, and a head mounted display (HMD) for implementing virtual reality and augmented reality.

The display device 10 according to an embodiment may include a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a curvature or may be formed at a right angle. The planar shape of the display panel 100 is not limited to the quadrangle, and may be formed similarly to other polygons, circles, or ovals. A planar shape of the display device 10 may follow the planar shape of the display panel 100, but the embodiment of the present specification is not limited thereto.

The display panel 100 may include a plurality of pixel areas PX, a plurality of scan lines SL, a plurality of emission control lines EL, a plurality of data lines DL, a scan driver 610, a light emitting driver 620, and a data driver 700. The display panel 100 may be divided into a display area DAA displaying an image and a non-display area NDA that does not display an image, as illustrated in FIG. 2. The plurality of pixel areas PX may be disposed in the display area DAA. The plurality of pixel areas PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

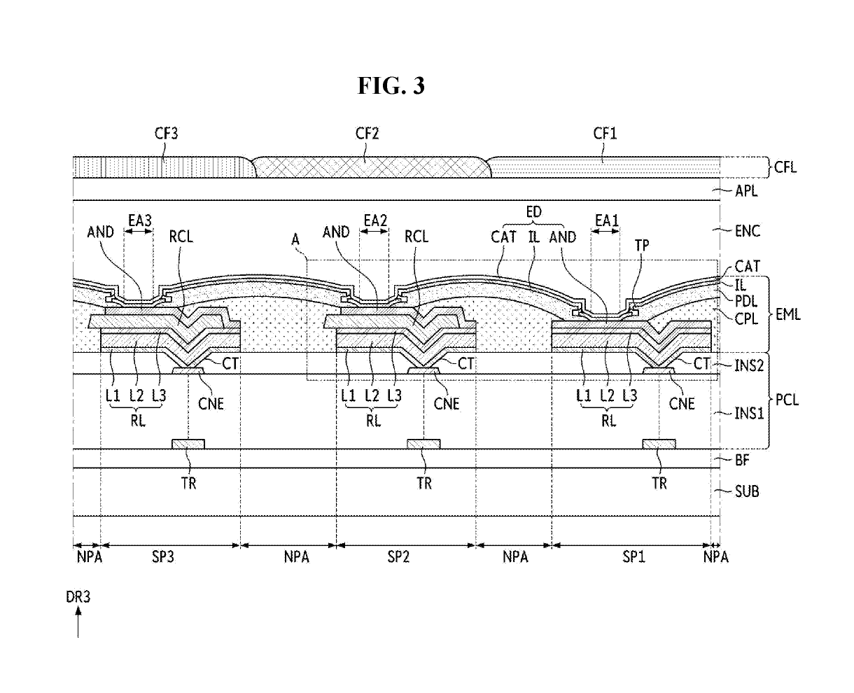

The plurality of pixel areas PX may include a plurality of sub-pixel areas SP1, SP2, and SP3. The plurality of sub-pixel areas SP1, SP2, and SP3 may include a plurality of transistors (e.g., pixel transistors; TR in FIG. 3).

The pixel circuit of each of the plurality of sub-pixel areas SP1, SP2, and SP3 (e.g., the pixel circuit including the pixel transistors) may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. The pixel circuit of each of the plurality of sub-pixel areas SP1, SP2, and SP3 may receive a data voltage of the data line DL according to a write scan signal of the write scan line GWL, and may emit light from a light emitting element according to the data voltage.

The scan driver 610, the light emitting driver 620, and the data driver 700 may be disposed in the non-display area NDA.

The scan driver 610 may include a plurality of scan transistors, and the light emitting driver 620 may include a plurality of light emitting transistors.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the pixel circuits of the sub-pixel areas SP1, SP2, and SP3 may be selected by the write scan signals of the scan driver 610, and the data voltages may be supplied to the selected sub-pixel areas SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, a rear surface of the display panel 100. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

The circuit board 300 may be electrically connected to a plurality of pads of the display panel 100 by using a conductive adhesive member such as an anisotropic conductive film. The circuit board 300 may be a flexible printed circuit board or flexible film made of a flexible material. It is illustrated in FIG. 1 that the circuit board 300 is unfolded, but the circuit board 300 may be bent. In this case, one end of the circuit board 300 may be disposed on the rear surface of the display panel 100 and/or a rear surface of the heat dissipation layer 200. The other end of the circuit board 300 may be connected to the pads of the display panel 100 by using a conductive adhesive member. One end of the circuit board 300 may be an end opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply the generated driving voltages to the display panel 100.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300 and the pads. In addition, the first driving voltage VSS, the second driving voltage VDD, and the third driving voltage VINT of the power supply circuit 500 may be supplied to the display panel 100 through the circuit board 300 and the pads.

Alternatively, each of the timing control circuit 400 and the power supply circuit 500 may be disposed in the non-display area NDA of the display panel 100, similarly to the scan driver 610, the light emitting driver 620, and the data driver 700. In this case, the timing control circuit 400 may include a plurality of timing transistors, and each power supply circuit 500 may include a plurality of power transistors.

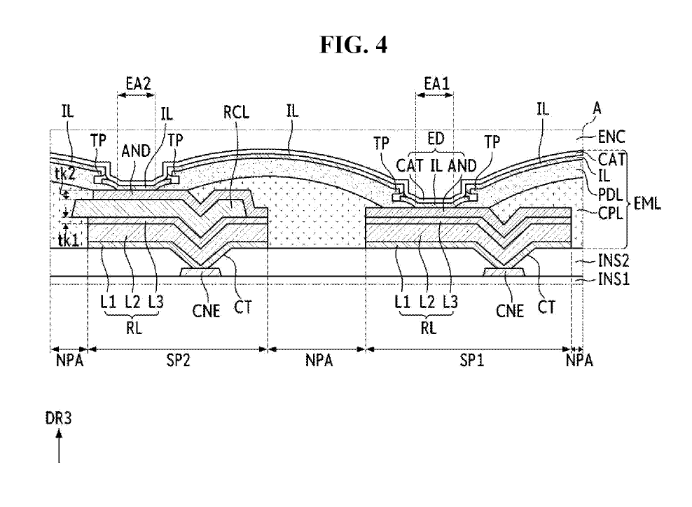

FIG. 3 is a cross-sectional view of the display device 10 according to an embodiment. For example, FIG. 3 may be a cross-sectional view of the display panel 100 of FIG. 2. Specifically, FIG. 3 may be a cross-sectional view of a display area DAA of the display panel 100. FIG. 4 is an enlarged view of area A of FIG. 3.

As illustrated in FIG. 3, the display device 10 may include a substrate SUB, a buffer layer BF on the substrate SUB, a pixel circuit layer PCL on the buffer layer BF, a light emitting element layer EML on the pixel circuit layer PCL, an encapsulation layer ENC on the light emitting element layer EML, an adhesive layer APL on the encapsulation layer ENC, and a color filter layer CFL on the adhesive layer APL. Here, the pixel circuit layer PCL may include the pixel circuit of the first sub-pixel area SP1, the pixel circuit of the second sub-pixel area SP2, and the pixel circuit of the third sub-pixel area SP3 described above.

The pixel circuit layer PCL may include a plurality of transistors TR (e.g., pixel transistors TR), a plurality of insulating layers INS1 and INS2, and a plurality of connection electrodes CNE.

The light emitting element layer EML may include a plurality of reflective electrodes RL, a plurality of resonance control layers RCL, a plurality of first electrodes AND (e.g., anode electrodes), a capping layer CPL, a pixel defining layer PDL, a light emitting stack layer IL, and a second electrode CAT (e.g., a cathode electrode).

The substrate SUB may include a first sub-pixel area SP1, a second sub-pixel area SP2, and a third sub-pixel area SP3.

A transistor TR, a reflective electrode RL, a first electrode AND, a light emitting stack layer IL, a second electrode CAT, and a first color filter CF1 may be disposed in the first sub-pixel area SP1. A transistor TR, a reflective electrode RL, a resonance control layer RCL, a first electrode AND, a light emitting stack layer IL, a second electrode CAT, and a second color filter CF2 may be disposed in the second sub-pixel area SP2. A transistor TR, a reflective electrode RL, a resonance control layer RCL, a first electrode AND, a light emitting stack layer IL, a second electrode CAT, and a third color filter CF3 may be disposed in the third sub-pixel area SP3.

The substrate SUB may be a base substrate SUB or a base member. The substrate SUB may be a flexible substrate SUB that may be bent, folded, rolled, or the like. For example, the substrate SUB may include a glass material or a metal material. Unlike this, the substrate SUB may include a polymer resin such as polyimide (PI).

A buffer layer BF may be disposed on the substrate SUB. The buffer layer BF may be a film for protecting the transistors TR of the pixel circuit layer PCL and the light emitting stack layer IL (or the light emitting layer of the light emitting stack layer IL) of the light emitting element layer EML from moisture permeating through the substrate SUB that is vulnerable to moisture permeation.

Transistors TR may be disposed on the buffer layer BF. For example, the transistors TR may be disposed on the buffer layer BF of the first sub-pixel area SP1, the second sub-pixel area SP2, and the third sub-pixel area SP3.

A first insulating layer INS1 may be disposed on the transistors TR. The first insulating layer INS1 may include a plurality of interlayer insulating layers stacked in the third direction DR3 on the transistors TR.

A plurality of connection electrodes CNE may be disposed on the first insulating layer INS1. The plurality of connection electrodes CNE may be connected to the plurality of transistors TR, respectively. For example, the transistor TR of the first sub-pixel area SP1 may be electrically connected to the connection electrode CNE of the first sub-pixel area SP1, the transistor TR of the second sub-pixel area SP2 may be electrically connected to the connection electrode CNE of the second sub-pixel area SP2, and the transistor TR of the third sub-pixel area SP3 may be electrically connected to the connection electrode CNE of the third sub-pixel area SP3. In this case, a drain electrode of the transistor TR may be connected to the connection electrode CNE through a plurality of intermediate connection electrodes CNE disposed between the transistor TR and the connection electrode CNE.

A second insulating layer INS2 may be disposed on the plurality of connection electrodes CNE. The second insulating layer INS2 may include a plurality of contact holes CT penetrating through the second insulating layer INS2. The plurality of contact holes CT may overlap with the plurality of connection electrodes CNE, respectively. For example, the plurality of connection electrodes CNE may be exposed through the plurality of contact holes CT, respectively.

A plurality of reflective electrodes RL may be disposed on the second insulating layer INS2. The plurality of reflective electrodes RL may be connected to the plurality of connection electrodes CNE through the plurality of contact holes CT of the second insulating layer INS2, respectively.

The reflective electrode RL may include a plurality of reflective layers sequentially stacked along the third direction DR3 on the second insulating layer INS2. For example, the reflective electrode RL may include a first layer L1, a second layer L2, and a third layer L3 disposed along the third direction DR3 between the second insulating layer INS2 and the first electrode AND (or the resonance control layer RCL). As a specific example, the reflective electrode RL of the first sub-pixel area SP1 may include a first layer L1, a second layer L2, and a third layer L3 disposed between the second insulating layer INS2 and the first electrode AND of the first sub-pixel area SP1. In addition, the reflective electrode RL of the second sub-pixel area SP2 may include a first layer L1, a second layer L2, and a third layer L3 disposed between the second insulating layer INS2 and the resonance control layer RCL of the second sub-pixel area SP2. In addition, the reflective electrode RL of the third sub-pixel area SP3 may include a first layer L1, a second layer L2, and a third layer L3 disposed between the second insulating layer INS2 and the resonance control layer RCL of the third sub-pixel area SP3.

The first layer L1 may be disposed on the second insulating layer INS2. The first layer L1 may be connected to the connection electrode CNE through the contact hole CT of the second insulating layer INS2. The first layer L1 may be made of a material including indium-tin-oxide (ITO). For example, the first layer L1 may be made of a material including crystalline indium-tin-oxide.

The second layer L2 may be disposed on the first layer L1. For example, the second layer L2 may be disposed between the first layer L1 and the third layer L3. The second layer L2 may be made of a material including silver (Ag).

The third layer L3 may be disposed on the second layer L2. For example, the third layer L3 of the first sub-pixel area SP1 may be disposed between the second layer L2 of the first sub-pixel area SP1 and the first electrode AND of the first sub-pixel area SP1. In addition, the third layer L3 of the second sub-pixel area SP2 may be disposed between the second layer L2 of the second sub-pixel area SP2 and the resonance control layer RCL of the second sub-pixel area SP2. In addition, the third layer L3 of the third sub-pixel area SP3 may be disposed between the second layer L2 of the third sub-pixel area SP3 and the resonance control layer RCL of the third sub-pixel area SP3.

The third layer L3 may be made of a material including an amorphous transparent conductive oxide (TCO). For example, the third layer L3 may include a transparent conductive oxide that may be robust to heat and may maintain an amorphous state at heat of 260 degrees in Celsius or less (e.g., heat during a heat treatment process). To this end, the third layer L3 according to an embodiment may be made of a material including tin (Sn) doped Indium-Zinc-Oxide (IZO). The third layer L3 according to another embodiment may be made of a material including any one of Indium-Zinc-Oxide (IZO), Indium-Gallium-Zinc-Oxide (IGZO), Indium-Tin-Zinc-Oxide (ITZO), Indium-Gallium-Oxide (IGO), Indium-Tin-Gallium-Oxide (ITGO), and Indium-Tin-Gallium-Zinc-Oxide (ITGZO). The transparent conductive oxides listed above may be maintained in an amorphous state at high temperatures of, for example, about 260 degrees in Celsius or less.

When the third layer L3 is made of a material including tin (Sn) doped Indium-Zinc-Oxide (IZO), the third layer L3 may include 12 atomic percentages (at%) to 22 at% of tin with respect to the total number of atoms in the third layer L3.

When the third layer L3 is made of IGZO, the composition of the third layer L3 may include about 44.2 weight percentages (wt%) of indium oxide (InOx), about 29.6 wt% of gallium oxide (GaOx), and about 25.9 wt% of zinc oxide (ZnOx) with respect to the total weight of the third layer L3.

When the third layer L3 is made of IZO, the composition of the third layer L3 may include 10 at% to 25 at% of zinc (Zn) and 75 at% to 90 at% of indium (In) with respect to the total number of atoms in the third layer L3. In addition, when the third layer L3 is made of IZO, the composition of the third layer L3 may include about 90 wt% of indium oxide (InOx) and about 10 wt% of zinc oxide (ZnOx) with respect to the total weight of the third layer L3.

When the third layer L3 is made of ZITO, the composition of the third layer L3 may include 6 at% to 22 at% of tin under the condition that the ratio of indium and zinc is 1:1 with respect to the total number of atoms in the third layer L3.

When the third layer L3 is made of IGO, the composition of the third layer L3 may include indium oxide (InOx) greater than 95 wt% and gallium oxide (GaOx) smaller than 5 wt% with respect to the total weight of the third layer L3.

The third layer L3 may also transform from amorphous to crystalline above a certain temperature. For example, in a process of forming the third layer L3 (e.g., a film deposition process of the third layer L3), the third layer L3 may have an amorphous state, but the third layer L3 may be transformed into a crystalline state by heat applied in a subsequent heat treatment process, etc. As a specific example, since a heat treatment process may be performed in a process of forming a capping layer CPL after the film deposition of the third layer L3, the amorphous third layer L3 may be transformed into a crystalline third layer L3 by the heat applied to the amorphous third layer L3 during the heat treatment process. In other words, the third layer L3 according to another embodiment may be made of a material including a crystalline transparent conductive oxide.

According to an embodiment, the third layer L3 may be deposited on the second layer L2 after the film deposition of the second layer L2. The second layer L2 and the third layer L3 may be in direct contact with each other. In this case, the third layer L3 on the second layer L2 may be maintained in an amorphous state at 260 degrees in Celsius or less after the film deposition. The third layer L3 may include an amorphous transparent oxide or a crystalline transparent conductive oxide at temperatures higher than 260 degrees in Celsius. For example, the third layer L3 may remain in the amorphous state or transformed from the amorphous state to the crystalline state at temperatures higher than 260 degrees in Celsius.

The third layer L3 and the second layer L2 may have different thicknesses. For example, the thickness of the second layer L2 may be greater than the thickness of the third layer L3. In addition, the thickness of the second layer L2 may be greater than a thickness of the first layer L1. In addition, the thickness of the first layer L1 and the thickness of the second layer L2 may be the same. However, the difference between the thickness of the first layer L1, the thickness of the second layer L2, and the thickness of the third layer L3 is not limited thereto and may be variously changed. Here, a thickness of the corresponding reflective layer may be a size of the corresponding reflective layer in the third direction DR3.

As described above, since the third layer L3 includes the amorphous transparent conductive oxide, the third layer L3 may be maintained in the amorphous state until the formation of the first electrode AND. For example, the third layer L3 may be maintained in the amorphous state until a patterning process of the first electrode AND. Therefore, after an etching process (e.g., a patterning process) for forming the first electrode AND and the reflective electrode RL, residue (e.g., residue of ITO) of the first electrode AND may be prevented from remaining in the non-pixel area NPA. When the residue of the first electrode AND exists in the non-pixel area NPA, a problem of short circuit in which the reflective electrodes RL and/or the first electrodes AND of adjacent sub-pixel areas are electrically connected to each other may occur.

A resonance control layer RCL may be disposed on the reflective electrodes RL. For example, the resonance control layer RCL may be disposed on the reflective electrode RL of the second sub-pixel area SP2 and the reflective electrode RL of the third sub-pixel area SP3, respectively. In other words, the resonance control layer RCL of the second sub-pixel area SP2 may be disposed between the third layer L3 of the second sub-pixel area SP2 and the first electrode AND of the second sub-pixel area SP2. In addition, the resonance control layer RCL of the third sub-pixel area SP3 may be disposed between the third layer L3 of the third sub-pixel area SP3 and the first electrode AND of the third sub-pixel area SP3. The resonance control layer RCL is not disposed on the reflective electrode RL of the first sub-pixel area SP1. A resonance distance of light emitted from each sub-pixel area may vary depending on the presence or absence of the resonance control layer RCL. Accordingly, since the reflectivity of light may be adjusted for each of the sub-pixel areas SP1, SP2, and SP3 that provide light of different wavelength bands, optical characteristics or image quality characteristics for a desired wavelength may be improved. One side of the resonance control layer RCL may be further extended into the non-pixel area NPA. For example, at least a portion of the resonance control layer RCL may be disposed in the non-pixel area NPA.

A first electrode AND may be disposed on the resonance control layer RCL. For example, the first electrode AND may be disposed on the resonance control layer RCL of the second sub-pixel area SP2 and the resonance control layer RCL of the third sub-pixel area SP3, respectively. In other words, the first electrode AND of the second sub-pixel area SP2 may be disposed between the resonance control layer RCL of the second sub-pixel area SP2 and the light emitting stack layer IL of the second sub-pixel area SP2. In addition, the first electrode AND of the third sub-pixel area SP3 may be disposed between the resonance control layer RCL of the third sub-pixel area SP3 and the light emitting stack layer IL of the third sub-pixel area SP3. The first electrode AND of the first sub-pixel area SP1 may be disposed between the third layer L3 of the first sub-pixel area SP1 and the light emitting stack layer IL of the first sub-pixel area SP1.

The first electrodes AND may be connected to the reflective electrodes RL, respectively. For example, the first electrode AND of the first sub-pixel area SP1 may be connected to the third layer L3 of the first sub-pixel area SP1, the first electrode AND of the second sub-pixel area SP2 may be connected to the third layer L3 of the second sub-pixel area SP2, and the first electrode AND of the third sub-pixel area SP3 may be connected to the third layer L3 of the third sub-pixel area SP3. In this case, since the resonance control layer RCL is not disposed in the first sub-pixel area SP1, a contact area between the first electrode AND and the third layer L3 of the first sub-pixel area SP1 may be greater than a contact area between the first electrode AND and the third layer L3 of the second sub-pixel area SP2 in which the resonance control layer RCL is disposed. Similarly, the contact area between the first electrode AND and the third layer L3 of the first sub-pixel area SP1 may be greater than a contact area between the first electrode AND and the third layer L3 of the third sub-pixel area SP3 in which the resonance control layer RCL is disposed.

The first electrode AND of the first sub-pixel area SP1 may be in contact (or in direct contact) with the entirety of an upper surface of the third layer L3 of the first sub-pixel area SP1, the first electrode AND of the second sub-pixel area SP2 may be in contact (or in direct contact) with an edge of the third layer L3 of the second sub-pixel area SP2, and the first electrode AND of the third sub-pixel area SP3 may be in contact (or in direct contact) with an edge of the third layer L3 of the third sub-pixel area SP3.

A thickness of the first electrode AND may be determined depending on the thickness of the third layer L3 described above. For example, since a thickness (hereinafter, a summed thickness) obtained by summing a thickness tk2 of the first electrode AND and a thickness tk1 of the third layer L3 may be 150 Å to 700 Å, the thickness tk2 of the first electrode AND and the thickness tk1 of the third layer L3 may each be adjusted to satisfy the range of the above-described summed thickness.

When the thickness tk1 of the third layer L3 is smaller than a preset lower limit threshold, the third layer L3 may be formed on the second layer L2 in an island shape, resulting in a problem in which the second layer is exposed, whereas when the thickness tk1 of the third layer L3 is greater than a preset upper limit threshold, a problem in which light transmittance efficiency may be reduced may occur. In addition, when the third layer L3 has an undercut shape due to an etching ratio between the resonance control layer RCL and the third layer L3, a poor contact (e.g., a poor contact between the first electrode AND and the reflective electrode RL) may occur between the first electrode AND and the third layer L3 in the second sub-pixel area SP2, if the thickness tk1 of the third layer L3 is greater than the upper limit threshold. Similarly, when the third layer L3 has the undercut shape as described above, a poor contact may occur between the first electrode AND and the third layer L3 in the third sub-pixel area SP3, if the thickness tk1 of the third layer L3 is greater than the upper limit threshold. Therefore, the thickness tk1 of the third layer L3 may be set to be greater than the lower limit threshold and smaller than the upper limit threshold. In this case, the lower limit threshold may be the above-described 30 Å, and the upper limit threshold may be the above-described 300 Å. However, the lower and upper limit thresholds of the third layer L3 are not limited to thereto and may be variously modified.

A capping layer CPL may be disposed on the first electrodes AND. The capping layer CPL may be disposed on edges of the plurality of first electrodes AND. In addition, the capping layer CPL may be disposed between adjacent sub-pixel areas. For example, the capping layer CPL may be disposed between the first sub-pixel area SP1 and the second sub-pixel area SP2, and between the second sub-pixel area SP2 and the third sub-pixel area SP3.

Specifically, when the area between the sub-pixel areas SP1, SP2, and SP3 of the display area DAA is defined as a non-pixel area NPA, the capping layer CPL may be disposed in the non-pixel area NPA. In this case, the capping layer CPL in the non-pixel area NPA may be disposed between adjacent reflective electrodes RL and between adjacent first electrodes AND. In addition, the capping layer CPL may also be disposed between the first electrode AND and the resonance control layer RCL disposed adjacent to each other. For example, the capping layer CPL may be disposed between the resonance control layer RCL of the second sub-pixel area SP2 and the first electrode AND of the third sub-pixel area SP3. As the non-pixel area NPA between the sub-pixel areas SP1, SP2, and SP3 is filled with the capping layer CPL, a step difference between the non-pixel area NPA and the sub-pixel areas SP1, SP2, and SP3 may be minimized.

A pixel defining layer PDL may be disposed on the capping layer CPL. The pixel defining layer PDL may be disposed on each edge of the first electrodes AND on the capping layer CPL. For example, the pixel defining layer PDL may have a plurality of light emitting areas EA1, EA2, and EA3 penetrating through the pixel defining layer PDL, and the plurality of light emitting areas EA1, EA2, and EA3 may expose a portion except for the edges of the first electrodes AND. The first electrodes AND may overlap the light emitting areas EA1, EA2, and EA3 of the pixel defining layer PDL, respectively. For example, the first light emitting area EA1 of the pixel defining layer PDL may overlap a central portion of the first electrode AND of the first sub-pixel area SP1, the second light emitting area EA2 of the pixel defining layer PDL may overlap a central portion of the first electrode AND of the second sub-pixel area SP2, and the third light emitting area EA3 of the pixel defining layer PDL may overlap a central portion of the first electrode AND of the third sub-pixel area SP3.

In addition, the pixel defining layer PDL may include a tip TP protruding toward each of the light emitting areas EA1, EA2, and EA3. An inner edge of the pixel defining layer PDL defining the light emitting area may have an undercut shape by the tip TP. To this end, according to an embodiment, the pixel defining layer PDL may have a structure in which two or more insulating layers having different etching rates are stacked. The tip TP of the pixel defining layer PDL may be a structure for cutting a light emitting stack layer IL, which will be described later.

A light emitting stack layer IL may be disposed on the first electrodes AND, the capping layer CPL, and the pixel defining layer PDL. In this case, the light emitting stack layer IL may be cut on the pixel defining layer PDL. For example, the light emitting stack layer IL may be cut on the tip TP of the pixel defining layer PDL. In cross-section view, the light emitting stack layer IL may be cut along the pixel defining layer PDL. Therefore, the light emitting stack layer IL may be divided into a portion that is in contact with the first electrode AND in each of the light emitting areas EA1, EA2, and EA3 and a portion that is disposed on an area (e.g., an upper surface of the pixel defining layer PDL) excluding each of the light emitting areas EA1, EA2, and EA3. In other words, the light emitting stack layer IL may be cut along the pixel defining layer PDL to be separated for each of the sub-pixel areas SP1, SP2, and SP3. Accordingly, lateral leakage current between the sub-pixel areas SP1, SP2, and SP3 adjacent to each other may be minimized. As the lateral leakage current is minimized, color mixing between the sub-pixel areas SP1, SP2, and SP3 adjacent to each other may be prevented, thereby improving an image quality of the display device 10.

The light emitting stack layer IL may include a plurality of stack layers sequentially stacked along the third direction DR3. For example, the light emitting stack layer IL may have a three-tandem structure including a first stack layer, a second stack layer on the first stack layer, and a third stack layer on the second stack layer. Here, the second stack layer may be disposed between the first stack layer and the third stack layer. The embodiment of the present specification is not limited thereto. For example, the light emitting stack layer IL may also have a two-tandem structure including two stack layers.

In the three-tandem structure, the first stack layer, the second stack layer, and the third stack layer of the light emitting stack layer IL may provide light of different colors (or wavelengths). For example, one of the first stack layer, the second stack layer, and the third stack layer may provide light of a first color (e.g., green), another of the first stack layer, the second stack layer, and the third stack layer may provide light of a second color (e.g., red), and the other of the first stack layer, the second stack layer, and the third stack layer may provide light of a third color (e.g., blue).

The first stack layer of the light emitting stack layer IL may have a structure in which a first hole transporting layer, a first organic light emitting layer, and a first electron transporting layer are sequentially stacked. The second stack layer of the light emitting stack layer IL may have a structure in which a second hole transporting layer, a second organic light emitting layer, and a second electron transporting layer are sequentially stacked. The third stack layer of the light emitting stack layer IL may have a structure in which a third hole transporting layer, a third organic light emitting layer, and a third electron transporting layer are sequentially stacked. Here, the first organic light emitting layer, the second organic light emitting layer, and the third organic light emitting layer may provide light of different colors (or wavelengths). For example, one of the first organic light emitting layer, the second organic light emitting layer, and the third organic light emitting layer may provide light of a first color (e.g., green), another of the first organic light emitting layer, the second organic light emitting layer, and the third organic light emitting layer may provide light of a second color (e.g., red), and the other of the first organic light emitting layer, the second organic light emitting layer, and the third organic light emitting layer may provide light of a third color (e.g., blue).

A first charge generating layer for supplying charges to the second stack layer and supplying electrons to the first stack layer may be disposed between the first stack layer and the second stack layer. The first charge generating layer may include an n-type charge generating layer that supplies electrons to the first stack layer and a p-type charge generating layer that supplies holes to the second stack layer. The n-type charge generating layer may include a dopant of a metallic material.

A second charge generating layer for supplying charges to the third stack layer and supplying electrons to the second stack layer may be disposed between the second stack layer and the third stack layer. The second charge generating layer may include an n-type charge generating layer that supplies electrons to the second stack layer and a p-type charge generating layer that supplies holes to the third stack layer.

The first stack layer may be disposed on the first electrodes AND and the pixel defining layer PDL. By means of the pixel defining layer PDL described above, the first stack layer of the light emitting stack layer IL may be disconnected between the sub-pixel areas SP1, SP2, and SP3 adjacent to each other. The second stack layer of the light emitting stack layer IL may be disposed on the first stack layer. By means of the pixel defining layer PDL described above, the second stack layer of the light emitting stack layer IL may be disconnected between the sub-pixel areas SP1, SP2, and SP3 adjacent to each other. The third stack layer of the light emitting stack layer IL may be disposed on the second stack layer. The third stack layer of the light emitting stack layer IL may not be disconnected by the pixel defining layer PDL and may be disposed to cover the second stack layer.

In the three-tandem structure, the pixel defining layer PDL may be a structure for disconnecting the first charge generating layer and the second charge generating layer of the light emitting element layer EML between the sub-pixel areas SP1, SP2, and SP3 adjacent to each other. In addition, in the two-tandem structure, the pixel defining layer PDL may be a structure for disconnecting a charge generating layer disposed between a lower stack layer and an upper stack layer.

A second electrode CAT may be disposed on the light emitting stack layer IL. For example, the second electrode CAT may be disposed on the third stack layer of the light emitting stack layer IL. For example, the second electrode CAT may not be disconnected by the pixel defining layer PDL and may be disposed on the third stack layer of the light emitting stack layer IL. The second electrode CAT may include a semi-transmissive conductive material such as magnesium (Mg), silver (Ag), or an alloy of magnesium (Mg) and silver (Ag). In this case, light emission efficiency may be increased in each of the first to third sub-pixel areas SP1, SP2, and SP3 by micro cavities.

An encapsulation layer ENC may be disposed on the second electrode CAT. The encapsulation layer ENC may include at least one inorganic layer to prevent oxygen or moisture from permeating into the light emitting element layer EML. For example, the encapsulation layer ENC may include a first encapsulation inorganic layer, an encapsulation organic layer, and a second encapsulation inorganic layer sequentially stacked along the third direction DR3.

An adhesive layer APL may be disposed on the encapsulation layer ENC. The adhesive layer APL may be a layer for increasing an interfacial adhesion between the encapsulation layer ENC and a color filter layer CFL to be described later. The adhesive layer APL may be an organic layer made of an acryl resin, an epoxy resin, a phenolic resin, a polyamide resin, a polyimide resin, or the like. The adhesive layer APL may be omitted.

A color filter layer CFL may be disposed on the adhesive layer APL. The color filter layer CFL may include a first color filter CF1, a second color filter CF2, and a third color filter CF3. The first color filter CF1 may be disposed on the adhesive layer APL in the first sub-pixel area SP1, the second color filter CF2 may be disposed on the adhesive layer APL in the second sub-pixel area SP2, and the third color filter CF3 may be disposed on the adhesive layer APL in the third sub-pixel area SP3. As described above, when the adhesive layer APL is omitted, the color filter layer CFL and the encapsulation layer ENC may be in direct contact with each other.

The first color filter CF1 may overlap the first light emitting area EA1 of the first sub-pixel area SP1. The first color filter CF1 may transmit first light (e.g., light in a green wavelength band). For example, the first color filter CF1 may transmit the first light among light emitted from the light emitting stack layer IL of the first light emitting area EA1.

The second color filter CF2 may overlap the second light emitting area EA2 of the second sub-pixel area SP2. The second color filter CF2 may transmit second light (e.g., light in a blue wavelength band). For example, the second color filter CF2 may transmit the second light among light emitted from the light emitting stack layer IL of the second light emitting area EA2.

The third color filter CF3 may overlap the third light emitting area EA3 of the third sub-pixel area SP3. The third color filter CF3 may transmit third light (e.g., light in a red wavelength band). For example, the third color filter CF3 may transmit the third light among light emitted from the light emitting stack layer IL of the third light emitting area EA3.

Although not illustrated, a plurality of lenses (e.g., micro lenses) overlapping the first color filter CF1, the second color filter CF2, and the third color filter CF3 may be disposed on the color filter layer CFL.

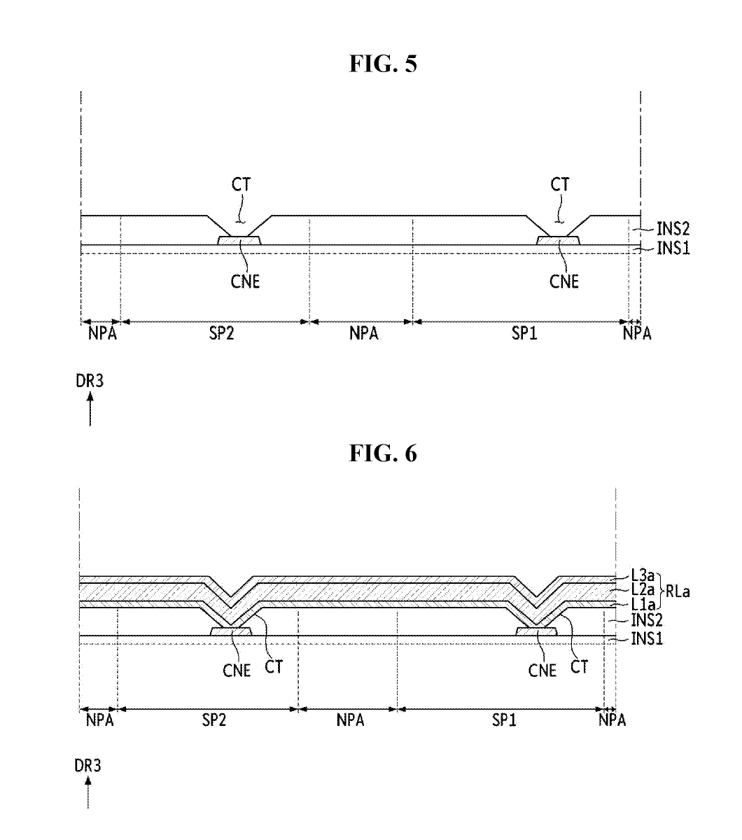

FIGS. 5, 6, 7, 8, 9, 10, 11, and 12 are process cross-sectional views for describing a method for fabricating a display device 10 according to an embodiment. For example, FIGS. 5-12 are process cross-sectional views for describing a method for fabricating the display device 10 of FIG. 4 described above.

First, as illustrated in FIGS. 3 and 5, a buffer layer BF may be formed on a substrate SUB, and then a plurality of transistors TR may be formed on the buffer layer BF, and then a first insulating layer INS1 may be formed on the plurality of transistors TR, and then a plurality of connection electrodes CNE may be formed on the first insulating layer INS1, and then a second insulating layer INS2 may be formed on the plurality of connection electrodes CNE. Thereafter, a plurality of contact holes CT penetrating through the second insulating layer INS2 and exposing the plurality of connection electrodes CNE may be formed.

Thereafter, as illustrated in FIG. 6, a preliminary reflective electrode RLa including a first preliminary layer L1a, a second preliminary layer L2a, and a third preliminary layer L3a may be formed on the second insulating layer INS2. For example, a first preliminary layer L1a may be formed on the second insulating layer INS2, and then a second preliminary layer L2a may be formed on the first preliminary layer L1a, and then a third preliminary layer L3a may be formed on the second preliminary layer L2a. In this case, the first preliminary layer L1a may include ITO (e.g., amorphous ITO), the second preliminary layer L2a may include a material including silver, and the third preliminary layer L3a may include a material including ITO (e.g., amorphous ITO). In addition, the third preliminary layer L3a may include the material including the amorphous transparent conductive oxide that is robust to heat as described above.

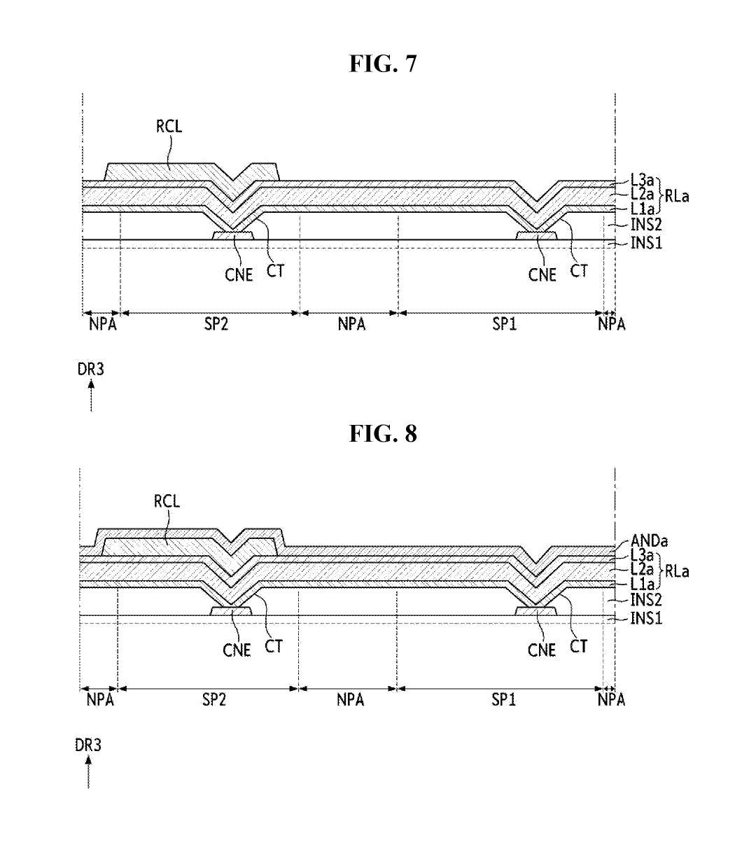

Next, as illustrated in FIG. 7, a resonance control layer RCL may be formed on the third preliminary layer L3a. For example, the resonance control layer RCL may be formed on the third preliminary layer L3a of the second sub-pixel area SP2 and the third sub-pixel area SP3. Here, the process of forming the resonance control layer RCL may include a process of depositing a layer (e.g., a silicon oxide layer; hereinafter, referred to as a preliminary resonance control layer RCL) that is a raw material for the resonance control layer RCL on the third preliminary layer L3a, a process of forming a photoresist pattern on the deposited preliminary resonance control layer RCL, and a process of etching (e.g., dry etching) the preliminary resonance control layer RCL using the photoresist pattern as a mask. In this case, heat applied during the process of depositing the preliminary resonance control layer RCL, heat applied during a pre-bake process of curing the photoresist pattern, and heat caused by plasma during the etching process may be applied to the third preliminary layer L3a. However, since the third preliminary layer L3a includes the amorphous transparent conductive oxide that is robust to heat as described above, the third preliminary layer L3a may be maintained in an amorphous state without being crystallized even by the heat described above. In other words, the third preliminary layer L3a may be maintained in the amorphous state during the process of forming the resonance control layer RCL. Since the first preliminary layer L1a is covered by a thick second layer L2 (e.g., the second layer L2 including a silver (Ag) material), the above-described heat may be applied relatively less to the first preliminary layer L1a (e.g., the first preliminary layer L1a including an ITO material). Accordingly, the first preliminary layer L1a may be maintained in the amorphous state during the process of forming the resonance control layer RCL.

Next, as illustrated in FIG. 8, a first preliminary electrode ANDa (e.g., a first preliminary electrode ANDa including an ITO material) may be formed on the resonance control layer RCL and the third preliminary layer L3a. The first preliminary electrode ANDa may be made of a material including ITO (e.g., amorphous ITO). Since heat may be applied when the first preliminary electrode ANDa is deposited, such heat may also be applied to the third preliminary layer L3a and the first preliminary layer L1a described above. In this case, for the reason described above, the third preliminary layer L3a and the first preliminary layer L1a may each be maintained in an amorphous state.

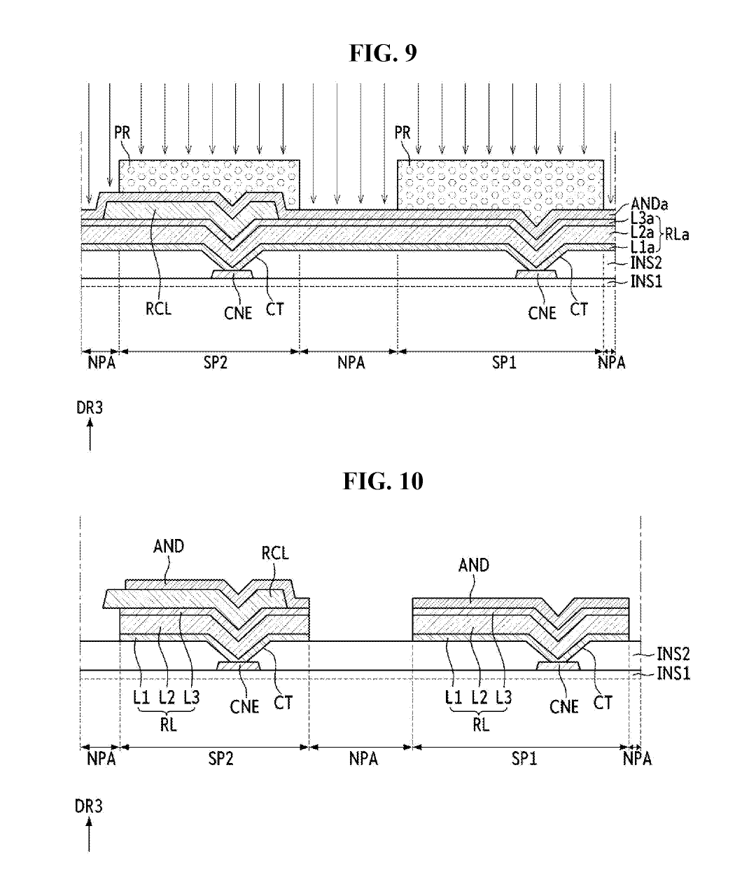

Thereafter, as illustrated in FIG. 9, a photoresist pattern PR may be disposed on the first preliminary electrode ANDa. For example, the photoresist pattern PR may be formed on the first preliminary electrode ANDa to overlap the first sub-pixel area SP1, the second sub-pixel area SP2, and the third sub-pixel area SP3. Next, the first preliminary electrode ANDa, the third preliminary layer L3a, the second preliminary layer L2a, and the first preliminary layer L1a may be simultaneously patterned (e.g., etched) using the photoresist pattern PR as a mask. For example, a portion of the first preliminary electrode ANDa that is exposed and not covered by the photoresist pattern PR may be removed by the etching process, a portion of the third preliminary layer L3a that is exposed and not covered by the photoresist pattern PR may be removed by the etching process, a portion of the second preliminary layer L2a that is exposed and not covered by the photoresist pattern PR may be removed by the etching process, and a portion of the first preliminary layer L1a that is exposed and not covered by the photoresist pattern PR may be removed by the etching process. In other words, by the patterning process using the above-described photoresist pattern PR as the mask, the first preliminary electrode ANDa, the third preliminary layer L3a, the second preliminary layer L2a, and the first preliminary layer L1a may remain in each of the sub-pixel areas SP1, SP2, and SP3 and be removed from the non-pixel area NPA between adjacent sub-pixel areas.

By the patterning process using the above-described photoresist pattern PR as the mask, a reflective electrode RL and a first electrode AND may be formed on the second insulating layer INS2 as illustrated in FIG. 10. For example, a reflective electrode RL including a first layer L1, a second layer L2, and a third layer L3 may be formed on the second insulating layer INS2 overlapping the first sub-pixel area SP1, the second sub-pixel area SP2, and the third sub-pixel area SP3, and a first electrode AND connected to the third layer L3 of the reflective electrode RL may be formed. As the first preliminary electrode ANDa, the third preliminary layer L3a, the second preliminary layer L2a, and the first preliminary layer L1a are removed from the non-pixel area NPA, the second insulating layer INS2 may be exposed in the non-pixel area NPA. In this case, as described above, since the third preliminary layer L3a is made of the material including the amorphous transparent conductive oxide, and furthermore, the first preliminary electrode ANDa may be maintained in the amorphous state by the third preliminary layer L3a in the amorphous state, and furthermore, the first layer L1 is covered by the thick second layer L2 and maintained in the amorphous state, residues of the first preliminary electrode ANDa, the third preliminary layer L3a, and the first preliminary layer L1a (e.g., residues of ITO) may not remain in the non-pixel area NPA during the patterning process for the first preliminary electrode ANDa, the third preliminary layer L3a, the second preliminary layer L2a, and the first preliminary layer L1a described above. For example, residue may not be formed in the non-pixel area NPA during the etching process. In particular, the third preliminary layer L3a that is not covered by the second layer L2 may be exposed to a heat source more times before the patterning process of the reflective electrode RL and the first electrode AND compared to the first preliminary electrode ANDa, and thus the possibility of crystallization of the third preliminary layer L3a is the highest. However, as described above, since the third preliminary layer L3a is made of a material including the amorphous transparent conductive oxide that is robust to heat, no residue of the third preliminary layer L3a is formed in the non-pixel area NPA after the patterning process. Since the first preliminary electrode ANDa is relatively less exposed to a heat source from the deposition process of the first preliminary electrode ANDa to the patterning process of the first preliminary electrode ANDa, the first preliminary electrode ANDa may be maintained in an amorphous state at a temperature of 260 degrees in Celsius or less until the first preliminary electrode ANDa is patterned (or before the first preliminary electrode ANDa is patterned). Therefore, after the first preliminary electrode ANDa is patterned, the residue of the first preliminary electrode ANDa (e.g., the ITO residue) may not be formed in the non-pixel area NPA.

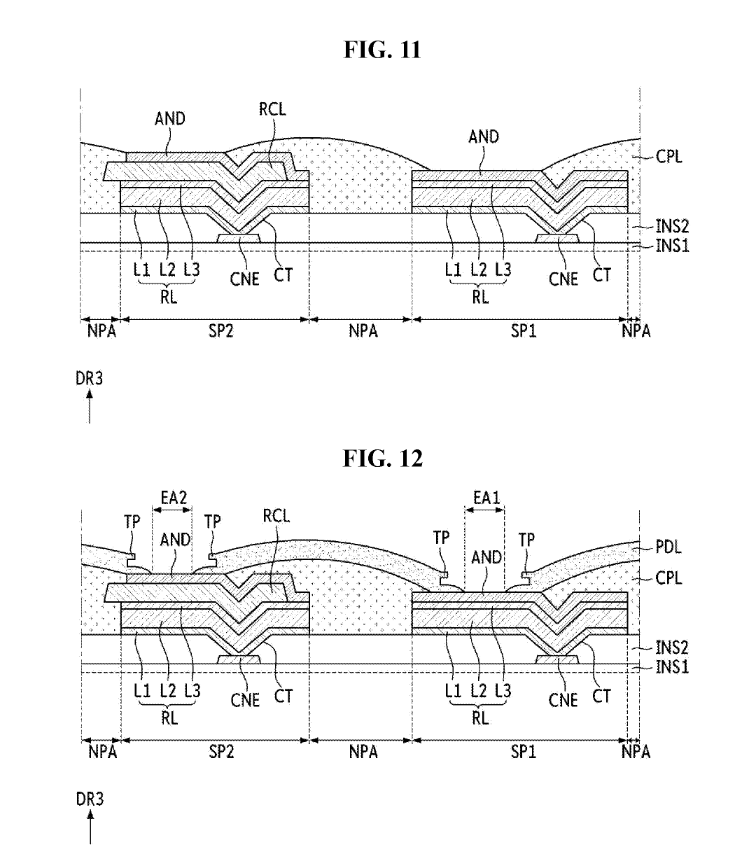

Thereafter, as illustrated in FIG. 11, a capping layer CPL that covers edges of the first electrodes AND and fills a gap (e.g., non-pixel area NPA) between adjacent sub-pixel areas may be formed. For example, the capping layer CPL may be formed on the edges of the first electrodes AND and the second insulating layer INS2 of the non-pixel area NPA. After forming the capping layer CPL, a heat treatment process of curing the capping layer CPL may be performed. Here, heat applied during the heat treatment process for the capping layer CPL may be higher than the heat applied in the processes performed prior to the process for the capping layer CPL (e.g., heat applied during the pre-bake process). By the heat applied during the heat treatment process for the capping layer CPL, the first layer L1 (e.g., the first layer L1 including the ITO material) and the first electrode AND (e.g., the first electrode AND including the ITO material) may be crystallized. For example, before the heat treatment process for the capping layer CPL, the first layer L1 and the first electrode AND may include an amorphous ITO material, whereas after the heat treatment process for the capping layer CPL, the first layer L1 and the first electrode AND may include a crystalline ITO material.

Before and after the heat treatment process for the capping layer CPL, the third layer L3 may include an amorphous transparent conductive oxide. In other words, the third layer L3 may be maintained in the same amorphous state before and after the heat treatment process for the capping layer CPL. However, the third layer L3 is not limited thereto, and may be maintained in an amorphous state before the heat treatment process for the capping layer CPL, and may be transformed into a crystalline state after the heat treatment process for the capping layer CPL, depending on the material composition of the third layer L3. According to an embodiment, since the first preliminary layer L1a, the third preliminary layer L3a, and the first preliminary electrode ANDa are all maintained in the amorphous state at temperatures of 260 degrees in Celsius or less, until the first preliminary layer L1a, the second preliminary layer L2a, the third preliminary layer L3a, and the first preliminary electrode ANDa are patterned into the first layer L1, the second layer L2, the third layer L3, and the first electrode AND through the etching process (or until the first preliminary electrode ANDa is patterned), the formation of residue (e.g., ITO residue) in the non-pixel area NPA after the patterning process may be prevented. Therefore, the problem of short circuit between the reflective electrodes RL of adjacent sub-pixel areas may be solved.

Next, as illustrated in FIG. 12, a pixel defining layer PDL may be formed on the capping layer CPL and the edges of the first electrodes AND. In this case, the pixel defining layer PDL may be formed on the first electrodes AND so that the light emitting areas EA1, EA2 and EA3 overlap the first electrodes AND.

Thereafter, as illustrated in FIG. 4, a light emitting stack layer IL may be formed on the first electrodes AND and the pixel defining layer PDL. In this case, the light emitting stack layer IL may be cut by a tip TP of the pixel defining layer PDL. Thereafter, a second electrode CAT may be formed on the light emitting stack layer IL, and then an encapsulation layer ENC may be formed on the second electrode CAT. Next, as illustrated in FIG. 3, an adhesive layer APL may be formed on the encapsulation layer ENC, and then a color filter layer CFL may be formed on the adhesive layer APL.

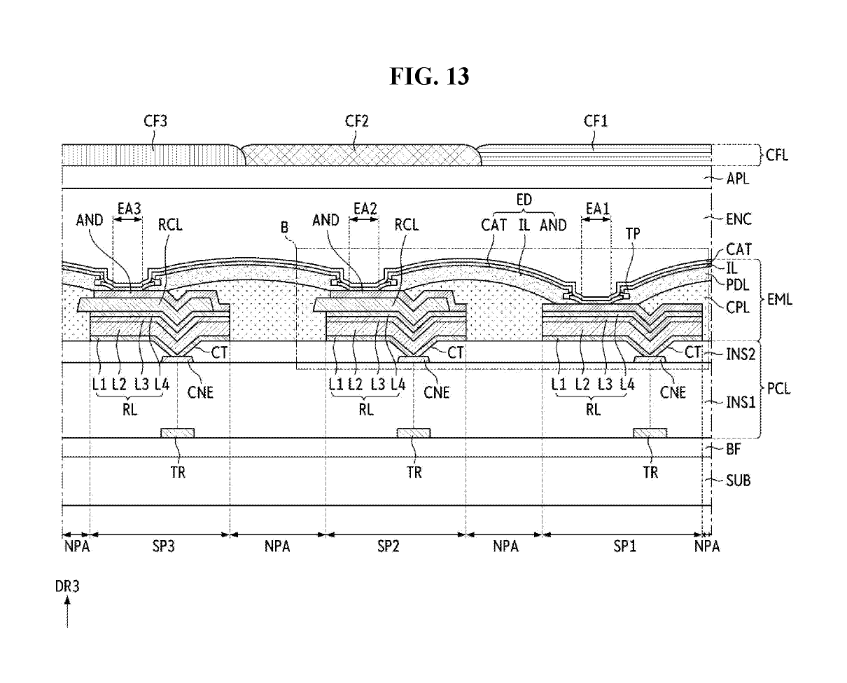

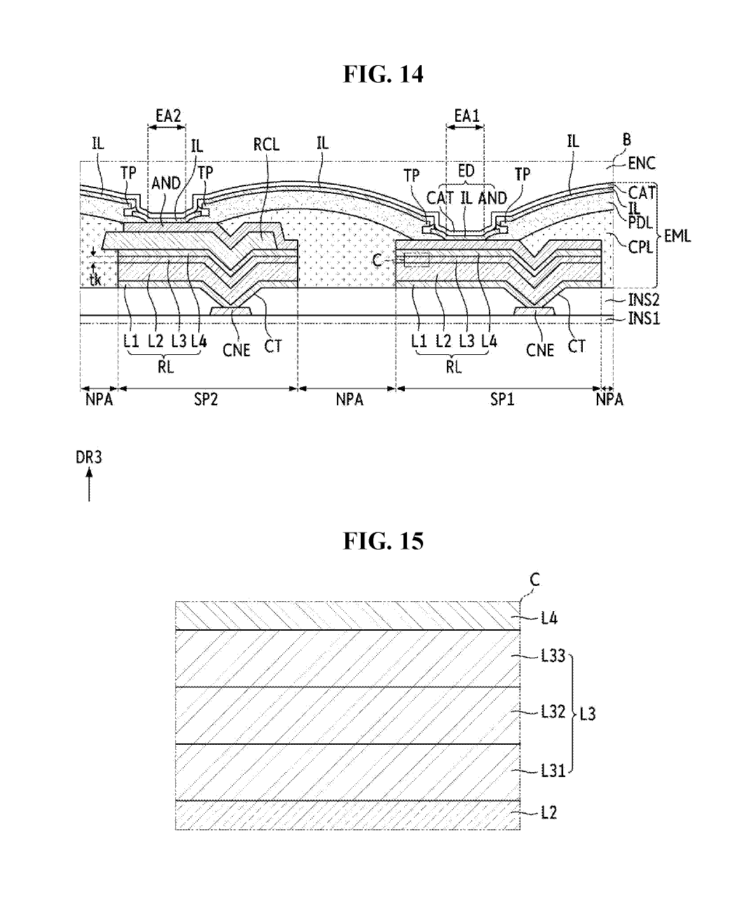

FIG. 13 is a cross-sectional view of a display device 10 according to an embodiment. For example, FIG. 13 may be a cross-sectional view of the display panel 100 of FIG. 2. Specifically, FIG. 13 may be a cross-sectional view of a display area DAA of the display panel 100. FIG. 14 is an enlarged view of area B of FIG. 13.

The display device 10 of FIGS. 13 and 14 is different from the display device 10 of FIGS. 3 and 4 in that the display device 10 of FIGS. 13 and 14 further includes a fourth layer L4, and such a difference will be mainly described as follows.

As illustrated in FIGS. 13 and 14, the reflective electrode RL may include a plurality of reflective layers sequentially stacked along the third direction DR3 on the second insulating layer INS2. For example, the reflective electrode RL may include a first layer L1, a second layer L2, a third layer L3, and a fourth layer L4 disposed along the third direction DR3 between the second insulating layer INS2 and the first electrode AND (or the resonance control layer RCL). As a specific example, the reflective electrode RL of the first sub-pixel area SP1 may include a first layer L1, a second layer L2, a third layer L3, and a fourth layer L4 disposed between the second insulating layer INS2 and the first electrode AND of the first sub-pixel area SP1. In addition, the reflective electrode RL of the second sub-pixel area SP2 may include a first layer L1, a second layer L2, a third layer L3, and a fourth layer L4 disposed between the second insulating layer INS2 and the resonance control layer RCL of the second sub-pixel area SP2. In addition, the reflective electrode RL of the third sub-pixel area SP3 may include a first layer L1, a second layer L2, a third layer L3, and a fourth layer L4 disposed between the second insulating layer INS2 and the resonance control layer RCL of the third sub-pixel area SP3.

Since the first layer L1, the second layer L2, and the third layer L3 of FIGS. 13 and 14 are substantially the same as the first layer L1, the second layer L2, and the third layer L3 of FIGS. 3 and 4 described above, descriptions of the first layer L1, the second layer L2, and the third layer L3 of FIGS. 13 and 14 refer to the descriptions related to FIGS. 3 and 4 described above.

The fourth layer L4 may be disposed on the third layer L3. For example, the fourth layer L4 of the first sub-pixel area SP1 may be disposed between the third layer L3 of the first sub-pixel area SP1 and the first electrode AND of the first sub-pixel area SP1. In addition, the fourth layer L4 of the second sub-pixel area SP2 may be disposed between the third layer L3 of the second sub-pixel area SP2 and the resonance control layer RCL of the second sub-pixel area SP2. In addition, the fourth layer L4 of the third sub-pixel area SP3 may be disposed between the third layer L3 of the third sub-pixel area SP3 and the resonance control layer RCL of the third sub-pixel area SP3. The fourth layer L4 may be made of a material including indium-tin-oxide (ITO).

When the fourth layer L4 and the first electrode AND are made of the same material, an interface between the fourth layer L4 and the first electrode AND may not exist. For example, when the fourth layer L4 and the first electrode AND are made of the same material, the fourth layer L4 and the first electrode AND may be made integrally with each other without an interface.

The first electrode AND may be disposed on the fourth layer L4 of the first sub-pixel area SP1, the resonance control layer RCL may be disposed on the fourth layer L4 of the second sub-pixel area SP2, and the resonance control layer RCL may be disposed on the fourth layer L4 of the third sub-pixel area SP3.

According to an embodiment, when the reflective electrode RL includes the first to fourth layers L1, L2, L3, and L4, the third layer L3 of the reflective electrode RL may have a thickness tk of 30 Å to 150 Å. The thickness tk of the third layer L3 may be a size of the third layer L3 in the third direction DR3 in the light emitting area (e.g., EA1). When the thickness tk of the third layer L3 is smaller than a lower limit threshold, the third layer L3 may be formed on the second layer L2 in an island shape, and when the thickness tk of the third layer L3 is greater than an upper limit threshold, light transmittance efficiency may be reduced. The thickness tk of the third layer L3 may be 30 Å to 150 Å. For example, the lower limit threshold for the thickness tk of the third layer L3 may be 30 Å, and the upper limit threshold may be 150 Å. As described above, even if the third layer L3 forms the undercut shape due to the etching ratio between the resonance control layer RCL and the third layer L3, the fourth layer L4 and the first electrode AND may be in contact with each other, thereby solving a problem of poor contact between the reflective electrode RL and the first electrode AND.

A total thickness summing the thickness tk of the third layer L3 and a thickness of the fourth layer L4 may be 300 Å. Here, the thickness of the fourth layer L4 may be a size of the fourth layer L4 in the third direction DR3.

FIG. 15 is a cross-sectional view for describing a configuration of a third layer L3 according to an embodiment. For example, FIG. 15 is an enlarged view of area C of FIG. 14.

As illustrated in FIG. 15, the third layer L3 may include a plurality of sub-layers including different materials. For example, the third layer L3 may include a first sub-layer L31 on the second layer L2, a second sub-layer L32 on the first sub-layer L31, and a third sub-layer L33 on the second sub-layer L32.

The first sub-layer L31, the second sub-layer L32, and the third sub-layer L33 may include different amorphous transparent conductive oxides. For example, the first sub-layer L31 may include an amorphous transparent conductive oxide including any one of IZO, IGZO, ITZO, IGO, ITGO, and ITGZO. In addition, the second sub-layer L32 may include an amorphous transparent conductive oxide including another one of IZO, IGZO, ITZO, IGO, ITGO, and ITGZO. In addition, the third sub-layer L33 may include an amorphous transparent conductive oxide including the other one of IZO, IGZO, ITZO, IGO, ITGO, and ITGZO.

FIG. 15 illustrates an example in which the third layer L3 includes three sub-layers L31, L32, and L33 including different amorphous transparent conductive oxides, but the number of the sub-layers L31, L32, and L33 is not limited thereto. For example, the third layer L3 may also include two sub-layers including different amorphous transparent conductive oxides. In addition, the third layer L3 may also include four or more sub-layers including different amorphous transparent conductive oxides.

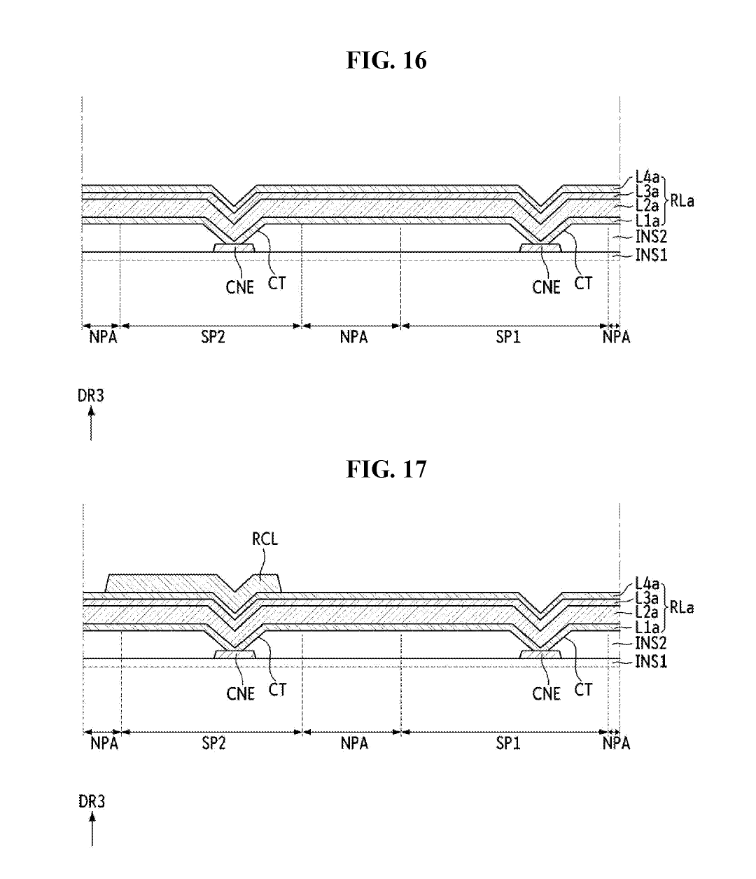

FIGS. 16, 17, 18, 19, 20, 21, and 22 are process cross-sectional views for describing a method for fabricating a display device 10 according to an embodiment. For example, FIGS. 16-22 are process cross-sectional views for describing a method for fabricating the display device 10 of FIG. 14 described above.

First, as illustrated in FIGS. 13 and 16, a buffer layer BF may be formed on a substrate SUB, and then a plurality of transistors TR may be formed on the buffer layer BF, and then a first insulating layer INS1 may be formed on the plurality of transistors TR, and then a plurality of connection electrodes CNE may be formed on the first insulating layer INS1, and then a second insulating layer INS2 may be formed on the plurality of connection electrodes CNE. Thereafter, a plurality of contact holes CT penetrating through the second insulating layer INS2 and exposing the plurality of connection electrodes CNE may be formed.

Thereafter, a preliminary reflective electrode RLa including a first preliminary layer L1a, a second preliminary layer L2a, a third preliminary layer L3a, and a fourth preliminary layer L4a may be formed on the second insulating layer INS2. For example, a first preliminary layer L1a may be formed on the second insulating layer INS2, and then a second preliminary layer L2a may be formed on the first preliminary layer L1a, then a third preliminary layer L3a may be formed on the second preliminary layer L2a, and then a fourth preliminary layer L4a may be formed on the third preliminary layer L3a. In this case, the fourth preliminary layer L4a may include a material including ITO (e.g., amorphous ITO). In addition, the third preliminary layer L3a may include a material including a heat-robust amorphous transparent conductive oxide as described above. In this case, since the third preliminary layer L3a includes a material including an amorphous transparent conductive oxide that has no directionality, the formation of a seed of the fourth preliminary layer L4a (e.g., the fourth preliminary layer L4a including ITO) formed on the third preliminary layer L3a may be suppressed.

Next, as illustrated in FIG. 17, a resonance control layer RCL may be formed on the fourth preliminary layer L4a. For example, the resonance control layer RCL may be formed on the fourth preliminary layer L4a of the second sub-pixel area SP2 and the third sub-pixel area SP3. Here, the first preliminary layer L1a, the third preliminary layer L3a, and the fourth preliminary layer L4a may each be maintained in an amorphous state. For a detailed description of the basis for the above, refer to the description related to the FIG. 7 described above.

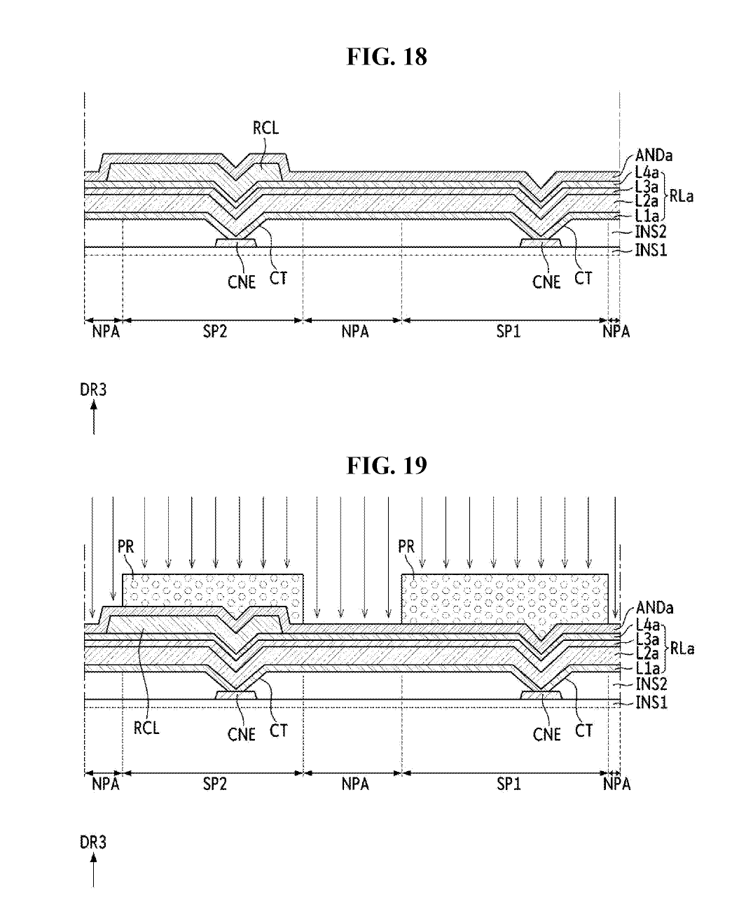

Next, as illustrated in FIG. 18, a first preliminary electrode ANDa (e.g., a first preliminary electrode ANDa including an ITO material) may be formed on the resonance control layer RCL and the fourth preliminary layer L4a. In this case, for the reason described above, the fourth preliminary layer L4a, the third preliminary layer L3a, and the first preliminary layer L1a may each be maintained in an amorphous state.

Thereafter, as illustrated in FIG. 19, a photoresist pattern PR may be disposed on the first preliminary electrode ANDa. For example, the photoresist pattern PR may be formed on the first preliminary electrode ANDa to overlap the first sub-pixel area SP1, the second sub-pixel area SP2, and the third sub-pixel area SP3. Next, the first preliminary electrode ANDa, the fourth preliminary layer L4a, the third preliminary layer L3a, the second preliminary layer L2a, and the first preliminary layer L1a may be simultaneously patterned (e.g., etched) using the photoresist pattern PR as a mask. For example, a portion of the first preliminary electrode ANDa that is exposed and not covered by the photoresist pattern PR may be removed by the etching process, a portion of the fourth preliminary layer L4a that is exposed and not covered by the photoresist pattern PR may be removed by the etching process, a portion of the third preliminary layer L3a that is exposed and not covered by the photoresist pattern PR may be removed by the etching process, a portion of the second preliminary layer L2a that is exposed and not covered by the photoresist pattern PR may be removed by the etching process, and a portion of the first preliminary layer L1a that is exposed and not covered by the photoresist pattern PR may be removed by the etching process. In other words, by the patterning process using the above-described photoresist pattern PR as the mask, the first preliminary electrode ANDa, the fourth preliminary layer L4a,the third preliminary layer L3a, the second preliminary layer L2a, and the first preliminary layer L1a may remain in each of the sub-pixel areas SP1, SP2, and SP3 and be removed from the non-pixel area NPA between adjacent sub-pixel areas.

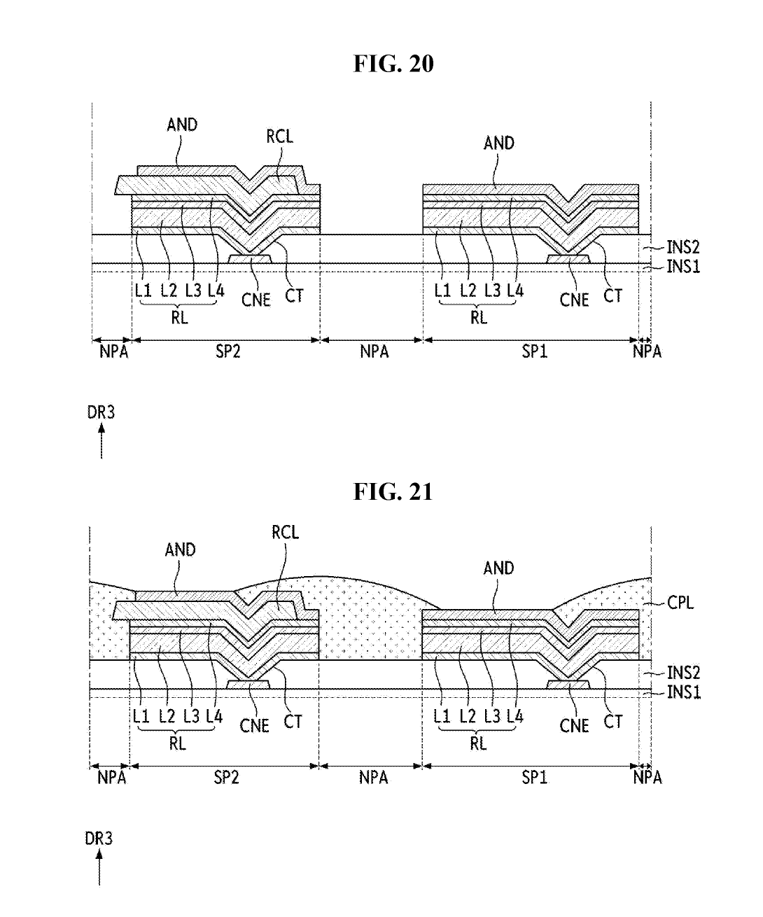

By the patterning process using the above-described photoresist pattern PR as the mask, a reflective electrode RL and a first electrode AND may be formed on the second insulating layer INS2 as illustrated in FIG. 20. For example, a reflective electrode RL including a first layer L1, a second layer L2, a third layer L3, and a fourth L4 may be formed on the second insulating layer INS2 overlapping the first sub-pixel area SP1, the second sub-pixel area SP2, and the third sub-pixel area SP3, and a first electrode AND connected to the fourth layer L4 of the reflective electrode RL may be formed. As the first preliminary electrode ANDa, the fourth preliminary layer L4a, the third preliminary layer L3a, the second preliminary layer L2a, and the first preliminary layer L1a are removed from the non-pixel area NPA, the second insulating layer INS2 may be exposed in the non-pixel area NPA. In this case, as described above, since the third preliminary layer L3a is made of the material including the amorphous transparent conductive oxide, and furthermore, the fourth preliminary layer L4a may be maintained in the amorphous state by the third preliminary layer L3a in the amorphous state, and furthermore, the first layer L1 is covered by the thick second layer L2 and maintained in the amorphous state, residues of the first preliminary electrode ANDa, the fourth preliminary layer L4a, the third preliminary layer L3a, and the first preliminary layer L1a (e.g., residues of ITO) may not remain in the non-pixel area NPA during the patterning process for the first preliminary electrode ANDa, the fourth preliminary layer L4a, the third preliminary layer L3a, the second preliminary layer L2a, and the first preliminary layer L1a described above. For example, residue may not be formed in the non-pixel area NPA during the etching process. In particular, the third preliminary layer L3a that is not covered by the second layer L2 may be exposed to a heat source more times before the patterning process of the reflective electrode RL and the first electrode AND compared to the first preliminary electrode ANDa, and thus the possibility of crystallization of the third preliminary layer L3a is the highest. However, as described above, since the third preliminary layer L3a is made of a material including the amorphous transparent conductive oxide that is robust to heat, no residue of the third preliminary layer L3a is formed in the non-pixel area NPA after the patterning process. Since the first preliminary electrode ANDa is relatively less exposed to a heat source from the deposition process of the first preliminary electrode ANDa to the patterning process of the first preliminary electrode ANDa, the first preliminary electrode ANDa may be maintained in an amorphous state at a temperature of 260 degrees in Celsius or less until the first preliminary electrode ANDa is patterned (or before the first preliminary electrode ANDa is patterned). Therefore, after the first preliminary electrode ANDa is patterned, the residue of the first preliminary electrode ANDa (e.g., the ITO residue) may not be formed in the non-pixel area NPA.

Thereafter, as illustrated in FIG. 21, a capping layer CPL that covers edges of the first electrodes AND and fills a gap (e.g., non-pixel area NPA) between adjacent sub-pixel areas may be formed. For example, the capping layer CPL may be formed on the edges of the first electrodes AND and the second insulating layer INS2 of the non-pixel area NPA. After forming the capping layer CPL, a heat treatment process of curing the capping layer CPL may be performed. Here, heat applied during the heat treatment process for the capping layer CPL may be higher than the heat applied in the processes performed prior to the process for the capping layer CPL (e.g., heat applied during the pre-bake process). By the heat applied during the heat treatment process for the capping layer CPL, the first layer L1 (e.g., the first layer L1 including the ITO material), the fourth layer L4 (e.g., the fourth layer L4 including the ITO material), and the first electrode AND (e.g., the first electrode AND including the ITO material) may be crystallized. For example, until the heat treatment process for the capping layer CPL, the first layer L1, the fourth layer L4, and the first electrode AND may include an amorphous ITO material, whereas after the heat treatment process for the capping layer CPL, the first layer L1, the fourth layer L4, and the first electrode AND may include a crystalline ITO material.

Before and after the heat treatment process for the capping layer CPL, the third layer L3 may include an amorphous transparent conductive oxide. In other words, the third layer L3 may be maintained in the same amorphous state before and after the heat treatment process for the capping layer CPL. However, the third layer L3 is not limited thereto, and may be maintained in an amorphous state before the heat treatment process for the capping layer CPL, and may be transformed into a crystalline state after the heat treatment process for the capping layer CPL, depending on the material composition of the third layer L3. According to an embodiment, since the first preliminary layer L1a, the third preliminary layer L3a, the fourth preliminary layer L4a, and the first preliminary electrode ANDa are all maintained in the amorphous state at temperatures of 260 degrees in Celsius or less, until the first preliminary layer L1a, the second preliminary layer L2a, the third preliminary layer L3a, the fourth preliminary layer L4a, and the first preliminary electrode ANDa are patterned into the first layer L1, the second layer L2, the third layer L3, the fourth layer L4, and the first electrode AND through the etching process (or until the first preliminary electrode ANDa is patterned), the formation of residue (e.g., ITO residue) in the non-pixel area NPA after the patterning process may be prevented. Therefore, the problem of short circuit between the reflective electrodes RL of adjacent sub-pixel areas SP1, SP2, and SP3 may be solved.

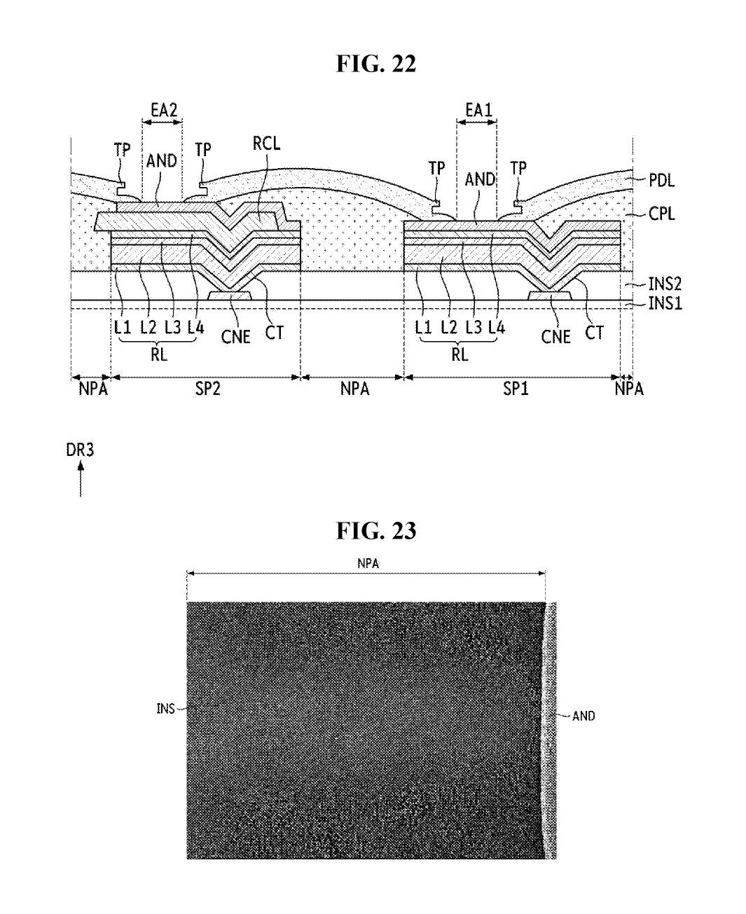

Next, as illustrated in FIG. 22, a pixel defining layer PDL may be formed on the capping layer CPL and the edges of the first electrodes AND. In this case, the pixel defining layer PDL may be formed on the first electrodes AND so that the light emitting areas overlap the first electrodes AND.

Thereafter, as illustrated in FIG. 14, a light emitting stack layer IL may be formed on the first electrodes AND and the pixel defining layer PDL. In this case, the light emitting stack layer IL may be cut by a tip TP of the pixel defining layer PDL. Thereafter, a second electrode CAT may be formed on the light emitting stack layer IL, and then an encapsulation layer ENC may be formed on the second electrode CAT. Next, as illustrated in FIG. 3, an adhesive layer APL may be formed on the encapsulation layer ENC, and then a color filter layer CFL may be formed on the adhesive layer APL.

FIG. 23 is a photograph of a non-pixel area of the display device 10 according to an embodiment.

As illustrated in FIG. 23, no ITO residue is formed in the non-pixel area NPA. For example, no ITO residue is formed on the second insulating layer INS2 in the non-pixel area NPA. Therefore, the problem of short circuit between the reflective electrodes RL in adjacent sub-pixel areas may be solved.

The display device 10 according to the embodiment may be applied to various electronic devices. An electronic device according to an embodiment may include the display device 10 described above, and may further include a module or device having additional functions in addition to the display device 10.

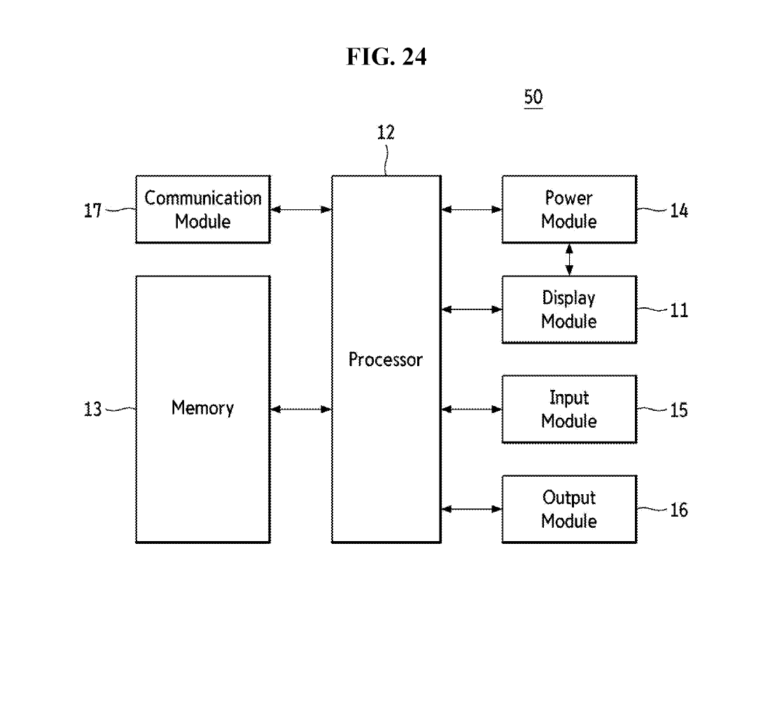

FIG. 24 is a block diagram of an electronic device according to an embodiment. Referring to FIG. 24, an electronic device 50 according to an embodiment may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and/or the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

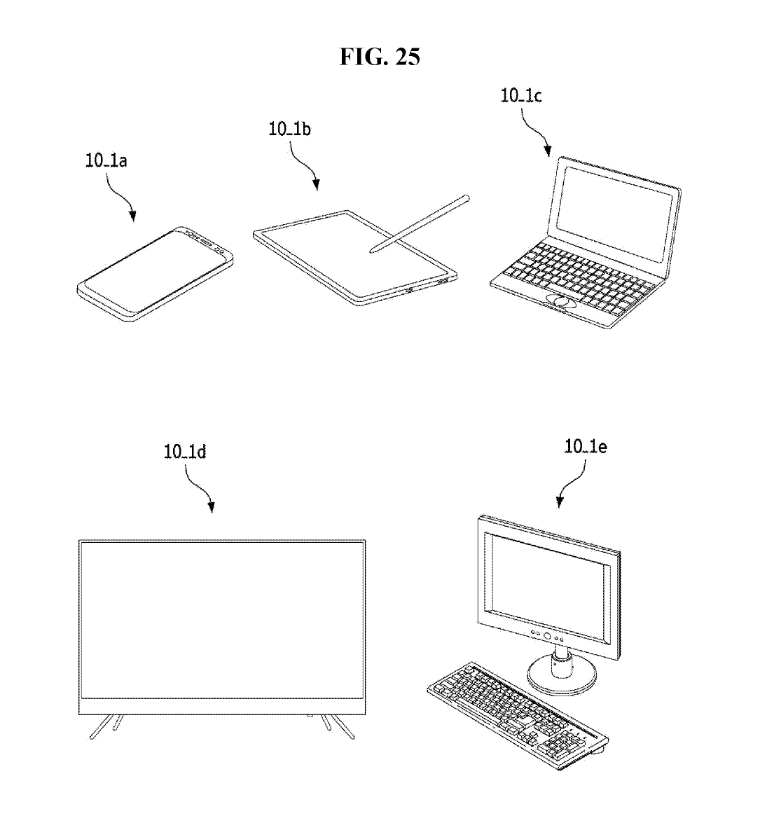

FIGS. 25, 26, and 27 are schematic diagrams of electronic devices according to various embodiments. FIGS. 25-27 illustrate examples of various electronic devices to which the display device 10 according to the embodiments is applied.

FIG. 25 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

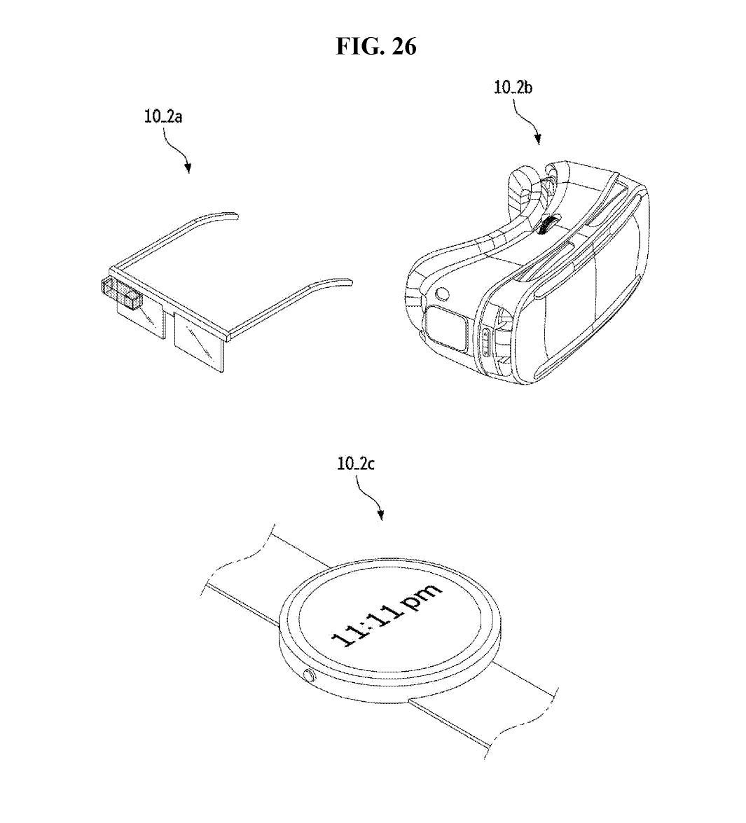

FIG. 26 illustrates a case in which an electronic device including a display module is applied to a wearable electronic device. The wearable electronic device may be a smart glasses 10_2a, a head mounted display 10_2b, a smart watch 10_2c, etc.

The smart glasses 10_2a and the head mounted display 10_2b may include a display module that emits a display image and a reflector that reflects the emitted display image and provides the reflected display image to the user's eyes, and may provide the user with a virtual reality or augmented reality screen through the display module and the reflector.

The smart watch 10_2c includes a biometric sensor as an input device and may provide the biometric information recognized by the biometric sensor to the user through the display module.

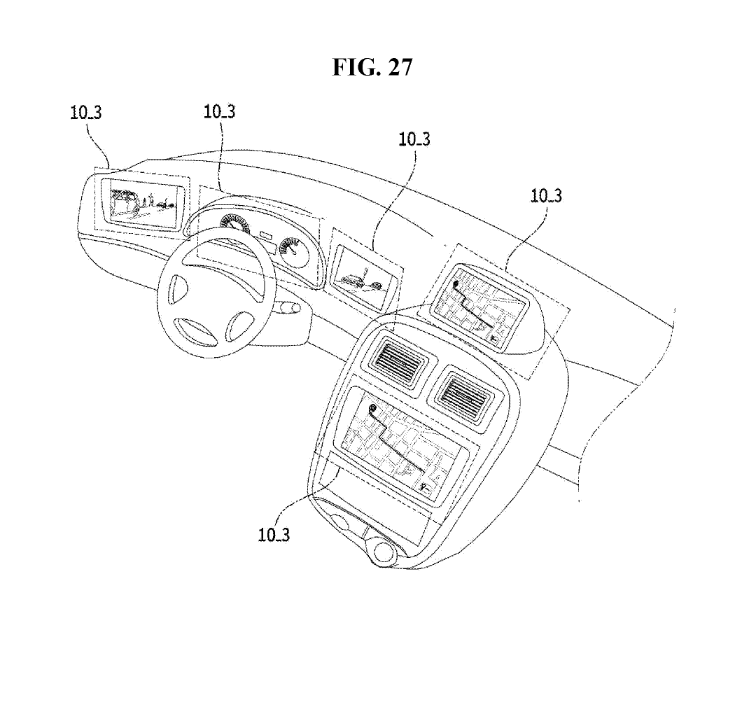

FIG. 27 illustrates an example in which an electronic device including a display module is applied to a vehicle. For example, an electronic device 10_3 may be applied to a dashboard, center fascia, etc. of an automobile, or may be applied to a Center Information Display (CID) disposed on the dashboard of the automobile or a room mirror display replacing a side mirror.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate including a sub-pixel area and a non-pixel area;
a transistor on the substrate;
a first insulating layer on the transistor;
a connection electrode disposed on the first insulating layer and connected to the transistor;
a second insulating layer on the connection electrode;
a reflective electrode disposed on the second insulating layer and connected to the connection electrode;
a first electrode on the reflective electrode;
a light emitting stack layer on the first electrode; and
a second electrode on the light emitting stack layer,
wherein the reflective electrode and the first electrode are disposed on the sub-pixel area,
the reflective electrode includes:
a first layer disposed between the second insulating layer and the first electrode and connected to the connection electrode;
a second layer disposed between the first layer and the first electrode and including silver; and
a third layer between the second layer and the first electrode,
the third layer and the second layer are in direct contact with each other, and
the third layer includes a transparent conductive oxide in an amorphous state at 260 degrees in Celsius or less after deposition.

2. The display device of claim 1, wherein the transparent conductive oxide in the third layer in a crystalline state at a temperature greater than 260 degrees in Celsius.

3. The display device of claim 1, wherein the third layer includes any one of tin (Sn)-doped Indium-Zinc-Oxide (IZO), IZO, Indium-Gallium-Zinc-Oxide (IGZO), Indium-Tin-Zinc-Oxide (ITZO), Indium-Gallium-Oxide (IGO), Indium-Tin-Gallium-Oxide (ITGO), and Indium-Tin-Gallium-Zinc-Oxide (ITGZO).

4. The display device of claim 3, wherein when the third layer includes the tin-doped IZO, the third layer includes 12 atomic percentages (at%) to 22 at% of tin with respect to a total number of atoms in the third layer.

5. The display device of claim 3, wherein when the third layer includes IGZO, the third layer includes about 44.2 weight percentages (wt%) of indium oxide, about 29.6 wt% of gallium oxide, and about 25.9 wt% of zinc oxide with respect to a total weight of the third layer.

6. The display device of claim 3, wherein when the third layer includes IZO, the third layer includes 10 at% to 25 at% of zinc and 75 at% to 90 at% of indium with respect to a total number of atoms in the third layer.

7. The display device of claim 3, wherein when the third layer includes IZO, the third layer includes about 90 wt% of indium oxide and about 10 wt% of zinc oxide with respect to a total weight of the third layer.

8. The display device of claim 3, wherein when the third layer includes ITZO, the third layer includes 6 at% to 22 at% of tin under a condition that a ratio of indium and zinc is 1:1 with respect to a total number of atoms in the third layer.

9. The display device of claim 3, wherein when the third layer includes IGO, the third layer includes indium oxide greater than 95 wt% and gallium oxide smaller than 5 wt% with respect to a total weight of the third layer.

10. The display device of claim 1, wherein the third layer has a thickness of about 300 angstroms (Å).

11. The display device of claim 1, wherein a total thickness summing a thickness of the first electrode and a thickness of the third layer is 150 Å to 700 Å.

12. The display device of claim 1, wherein the sub-pixel area is configured to provide green light.

13. The display device of claim 1, further comprising a resonance control layer between the third layer and the first electrode,
wherein the sub-pixel area is configured to provide either red light or blue light.

14. The display device of claim 1, wherein the first layer and the first electrode each include crystalline ITO, and
the second layer includes silver.

15. The display device of claim 1, wherein the reflective electrode further includes a fourth layer between the third layer and the first electrode, and
the fourth layer includes crystalline ITO.

16. The display device of claim 15, wherein a thickness of the third reflective layer is 30 Å to 150 Å, and
a total thickness summing the thickness of the third reflective layer and a thickness of the fourth reflective layer is 300 Å.

17. The display device of claim 1, wherein the third layer includes a plurality of sub-layers including different transparent conductive oxides.

18. The display device of claim 1, further comprising:
a capping layer disposed on an edge of the first electrode and the non-pixel area; and
a pixel defining layer disposed on the edge of the first electrode and the capping layer and defining a light emitting area overlapping the first electrode.

19. An electronic device comprising:
a processor;
a memory connected to the processor; and
a display device connected to the processor and the memory,
wherein the display device includes:
a substrate including a sub-pixel area and a non-pixel area;
a transistor on the substrate;
a first insulating layer on the transistor;
a connection electrode disposed on the first insulating layer and connected to the transistor;
a second insulating layer on the connection electrode;
a reflective electrode disposed on the second insulating layer and connected to the connection electrode;
a first electrode on the reflective electrode;
a light emitting stack layer on the first electrode; and
a second electrode on the light emitting stack layer,
wherein the reflective electrode and the first electrode are disposed on the sub-pixel area,
the reflective electrode includes:
a first layer disposed between the second insulating layer and the first electrode and connected to the connection electrode;
a second layer disposed between the first layer and the first electrode and including silver; and
a third layer between the second layer and the first electrode,
the third layer and the second layer are in direct contact with each other, and
the third layer includes a transparent conductive oxide in an amorphous state at 260 degrees in Celsius or less.

20. A method for fabricating a display device, the method comprising:
preparing a substrate including a first sub-pixel area, a second sub-pixel area, and a non-pixel area;
forming a first transistor and a second transistor on the substrate;
forming a first insulating layer on the first transistor and the second transistor;
forming a first connection electrode connected to the first transistor and a second connection electrode connected to the second transistor on the first insulating layer;
forming a second insulating layer on the first connection electrode and the second connection electrode;
forming a first contact hole exposing the first connection electrode and a second contact hole exposing the second connection electrode in the second insulating layer;
forming, on the second insulating layer, a first preliminary layer connected to the first connection electrode and the second connection electrode through the first contact hole and the second contact hole, respectively, and including amorphous ITO;
forming a second preliminary layer on the first preliminary layer;
forming a third preliminary layer including an amorphous transparent conductive oxide on the second preliminary layer;
forming a resonance control layer on the third preliminary layer of the second sub-pixel area;
forming a first preliminary electrode on the third preliminary layer and the resonance control layer;
forming a photoresist pattern on the first preliminary electrode of the first sub-pixel area and the second sub-pixel area;
forming a first_first reflective layer connected to the first connection electrode, a first_second reflective layer disposed on the first_first reflective layer, a first_third reflective layer disposed on the first_second reflective layer, and a first_first electrode disposed on the first_third reflective layer in the first sub-pixel area, and forming a second_first reflective layer connected to the second connection electrode, a second_second reflective layer disposed on the second_first reflective layer, a second_third reflective layer disposed on the second_second reflective layer, and a second_first electrode disposed on the second_third reflective layer and the resonance control layer in the second sub-pixel area, by patterning the first preliminary layer, the second preliminary layer, the third preliminary layer, and the first preliminary electrode using the photoresist pattern as a mask;
forming a capping layer on edges of the first_first electrode and the second_first electrode and on the second insulating layer of the non-pixel area; and
heat treating the capping layer,
wherein before the heat treating of the capping layer, the first_first reflective layer, the first_first electrode, the second_first reflective layer, and the second_first electrode each include an amorphous ITO material, and after the heat treating of the capping layer, the first_first reflective layer, the first_first electrode, the second_first reflective layer, and the second_first electrode each include a crystalline ITO material, and
before the first_first electrode and the second_first electrode are formed, the first_third reflective layer and the second_third reflective layer each include an amorphous transparent conductive oxide.
